(19) United States
(12) Patent Application Publication
(10) Pub. No.: US 2023/0203376 A1
(43) Pub. Date: Jun. 29, 2023

(54) LIQUID CRYSTAL POLYMER FILM, FLEXIBLE COPPER-CLAD LAMINATED BOARD, AND MANUFACTURING METHOD OF LIQUID CRYSTAL POLYMER FILM

(71) Applicant: FUJIFILM Corporation, Tokyo (JP)

(72) Inventor: Shuto KONO, Shizuoka (JP)

(73) Assignee: FUJIFILM Corporation, Tokyo (JP)

(21) Appl. No.: 18/173,064

(22) Filed: Feb. 23, 2023

Related U.S. Application Data
(63) Continuation of application No. PCT/JP2021/036294, filed on Sep. 30, 2021.

(30) Foreign Application Priority Data
Sep. 30, 2020 (JP) 2020-166406

(51) Int. Cl. C09K 19/38; B29C 48/08; B29C 48/14

(52) U.S. Cl. CPC C09K 19/3809; B29C 48/08; B29C 48/146; C09K 2219/03; B29C 2948/92152; B29C 2948/922; B29C 2948/92238; B29K 2105/0079

(57) ABSTRACT

Provided are a liquid crystal polymer film including a liquid crystal polymer, in which a melting point is 315° C. or higher and a number-average molecular weight is 13,000 or more and 150,000 or less; a flexible copper-clad laminated board; and a manufacturing method of a liquid crystal polymer film.

### CROSS-REFERENCE TO RELATED APPLICATION

This application is a Continuation of International Application No. PCT/JP2021/036294, filed Sep. 30, 2021, which claims priority to Japanese Patent Application No. 2020-166406 filed Sep. 30, 2020. Each of the above applications is hereby expressly incorporated by reference, in its entirety, into the present application.

### BACKGROUND OF THE INVENTION

### 1. Field of the Invention

The present disclosure relates to a liquid crystal polymer film, a flexible copper-clad laminated board, and a manufacturing method of a liquid crystal polymer film.

### 2. Description of the Related Art

A polymer film including a liquid crystal polymer (LCP) has characteristics of low dielectric constant, high heat resistance, low hygroscopicity, and excellent high frequency characteristics. Therefore, the polymer film is suitable as a substrate film for a circuit board. In particular, in recent years, the polymer film including a liquid crystal polymer has been developed as a substrate film for a circuit board for a fifth generation (5G) mobile communication system.

However, since the liquid crystal polymer has a rod-like molecular structure even in a molten state, the liquid crystal polymer has easy aligning properties. In a case of melt-extruding the liquid crystal polymer from a T-die for processing, the liquid crystal polymer receives shear stress in a die slit, rod-like liquid crystal molecules are aligned in a machine axis direction (machine direction; MD direction).

Therefore, in the polymer film including a liquid crystal polymer, which is manufactured by the melt extrusion, the liquid crystal polymer is a uniaxially aligned film along the MD direction, and have strong anisotropy. As a result, the polymer film including a liquid crystal polymer may have a drawback that it is easily torn in the MD direction.

Therefore, studies have been conducted to make an improvement on the easiness of tearing, which is the drawback of the polymer film including a liquid crystal polymer.

For example, JP2000-290512A proposes a polymer film containing a thermoplastic liquid crystal polymer and an amorphous polymer.

In addition, JP2020-33544A proposes a polymer film consisting of a liquid crystal polyester resin having a specific molecular weight distribution.

Furthermore, JP1989-279922A (JP-H1-279922A) proposes a liquid crystal resin molded product consisting of a liquid crystal polyarylate resin or liquid crystal polyester amide resin having a mesogen group as a main chain, in which a specific surface area thereof is 0.29 m²/g or more.

### SUMMARY OF THE INVENTION

In the polymer film of JP2000-290512A, dielectric constant may be increased in a case where tear resistance is improved. In order to use the polymer film including a liquid crystal polymer as, for example, a substrate film for a circuit board, it is preferable that the dielectric constant is low. Therefore, for example, in a case where the polymer film of JP2000-290512A is used as the substrate film for a circuit board, it had been found that the tear resistance cannot be sufficiently improved.

The polymer film of JP2020-33544A is manufactured by applying a solution which is obtained by dissolving the liquid crystal polyester resin in a solvent onto a support, and then removing the solvent. In order to improve tear resistance of the polymer film, it is preferable to increase a molecular weight of the liquid crystal polyester resin. However, in a case where the molecular weight of the liquid crystal polyester resin is increased, solubility in the solvent may decrease. Therefore, in the polymer film of JP2020-33544A, the molecular weight of the liquid crystal polyester resin may not be sufficiently increased during the manufacturing. Accordingly, in the polymer film of JP2020-33544A, it had been found that the tear resistance cannot be sufficiently improved.

In the liquid crystal resin molded product of JP1989-279922A (JP-H1-279922A), a fiber having improved tear resistance is obtained by forming the liquid crystal resin molded product into a fibrous form. However, in a case where the liquid crystal resin molded product of JP1989-279922A (JP-H1-279922A) is formed into a film form, film-forming properties may be deteriorated.

As described above, the polymer film including a liquid crystal polymer in the related art has not been excellent in both the tear resistance and the film-forming properties.

The present disclosure has been made in view of the above.

An object to be achieved by an embodiment of the present disclosure is to provide a liquid crystal polymer film having high tear resistance and excellent film-forming properties, a flexible copper-clad laminated board, and a manufacturing method of a liquid crystal polymer film.

The above-described objects have been achieved by the following methods. That is,

<1> A liquid crystal polymer film comprising:

a liquid crystal polymer,

in which the liquid crystal polymer film has a melting point of 315° C. or higher and has a number-average molecular weight of 13,000 or more and 150,000 or less.

<2> The liquid crystal polymer film according to <1>,

in which the liquid crystal polymer film has a number-average molecular weight of 18,000 or more and 150,000 or less.

<3> The liquid crystal polymer film according to <1> or <2>,

having a melt viscosity of 80 Pa·s or more and 400 Pa·s or less in a case where a temperature is set to be higher than the melting point by 5° C. and a shear rate is set to be 1000 sec⁻¹.

<4> The liquid crystal polymer film according to any one of <1> to <3>,

having an amount of heat of crystal melting, which is determined by a differential scanning calorimetry, of 2 J/g or less.

<5> The liquid crystal polymer film according to any one of <1> to <4>,

in which the liquid crystal polymer film is used in a flexible printed circuit board.

<6> A flexible copper-clad laminated board comprising:

the liquid crystal polymer film according to any one of <1> to <5>; and

a copper foil disposed on at least one surface of the liquid crystal polymer film.

<7> A manufacturing method of the liquid crystal polymer film according to any one of <1> to <5>, the manufacturing method comprising:

a film forming step of extruding a melt-kneaded liquid crystal polymer with a T-die to form a film.

<8> The liquid crystal polymer film according to any one of <1> to <5>,

in which, in a cross section of the liquid crystal polymer film along a thickness direction of the liquid crystal polymer film, in a case where an elastic modulus at a position A at a distance of half of a thickness of the liquid crystal polymer film from one surface toward the other surface of the liquid crystal polymer film is defined as an elastic modulus A and an elastic modulus at a position B at a distance of ⅛ of the thickness of the liquid crystal polymer film from one surface toward the other surface of the liquid crystal polymer film is defined as an elastic modulus B, a ratio B/A of the elastic modulus B to the elastic modulus A is 0.99 or less and the elastic modulus A is 4.0 GPa or more.

<9> The liquid crystal polymer film according to <8>,

in which the elastic modulus A is 4.6 GPa or more.

<10> The liquid crystal polymer film according to any one of <1> to <5>,

in which in a case where a cross section of the liquid crystal polymer film along a thickness direction of the liquid crystal polymer film is exposed and immersed in monomethylamine, and then void regions are extracted from an observed image of the cross section, obtained by using an electron microscope, an average value of widths of the void regions is 0.01 to 0.1 μm, and

an area ratio of the void regions in the observed image of the cross section is 20% or less.

<11> The liquid crystal polymer film according to <10>,

in which the void regions have an average length of 3 to 5 μm.

<12> The liquid crystal polymer film according to <10> or <11>,

in which the liquid crystal polymer film has a thickness of 15 μm or more and satisfies Requirement A,

Requirement A: in the cross section, in a case where a region where a distance from one surface of the liquid crystal polymer film is within 5 μm is defined as a first surface layer region, a region where a distance from the other surface of the liquid crystal polymer film is within 5 μm is defined as a second surface layer region, and a region within 2.5 μm from a center line equidistant from both surfaces of the liquid crystal polymer film is defined as a central layer region, an area ratio of void regions in the central layer region is higher than an area ratio of void regions in the first surface layer region and is also higher than an area ratio of void regions in the second surface layer region.

<13> The liquid crystal polymer film according to any one of <1> to <5>,

in which, in a cross section of the liquid crystal polymer film along a thickness direction of the liquid crystal polymer film, in a case where a hardness at a position A at a distance of half of a thickness of the liquid crystal polymer film from one surface toward the other surface of the liquid crystal polymer film is defined as a hardness A and a hardness at a position B at a distance of 1/10 of the thickness of the liquid crystal polymer film from one surface toward the other surface of the liquid crystal polymer film is defined as a hardness B, the hardness A and the hardness B satisfy a relationship of Expression (1A), and

in the cross section, in a case where a position at the distance of 1/10 of the thickness of the liquid crystal polymer film from the one surface toward the other surface of the liquid crystal polymer film is defined as a position T1, a position at a distance of 4/10 of the thickness of the liquid crystal polymer film from the one surface toward the other surface of the liquid crystal polymer film is defined as a position T2, and a position at a distance of 6/10 of the thickness of the liquid crystal polymer film from the one surface toward the other surface of the liquid crystal polymer film is defined as a position T3, a region from the one surface to the position T1 is defined as an S region, and a region from the position T2 to the position T3 is defined as a C region, an area ratio of void regions in the S region is defined as a void area proportion X, and an area ratio of void regions in the C region is defined as a void area proportion Y, the void area proportion X and the void area proportion Y satisfy a relationship of Expression (2A),

(Hardness A+Hardness B)/2≥0.10 GPa Expression (1A)

Void area proportion Y−Void area proportion X≥0.10%. Expression (2A)

<14> The liquid crystal polymer film according to <13>,

in which the hardness A and the hardness B satisfy a relationship of Expression (1B),

(Hardness A−Hardness B)≥−0.02 GPa. Expression (1B)

<15> The liquid crystal polymer film according to any one of <1> to <5> or <8> to <14>,

in which the liquid crystal polymer film has a monolayer structure.

<16> The liquid crystal polymer film according to any one of <1> to <5> or <8> to <15>,

in which the liquid crystal polymer film has a dielectric loss tangent of 0.0022 or less at a temperature of 23° C. and a frequency of 28 GHz.

<17> The liquid crystal polymer film according to any one of <1> to <5> or <8> to <16>,

in which the liquid crystal polymer has at least one selected from the group consisting of a repeating unit derived from parahydroxybenzoic acid and a repeating unit derived from 6-hydroxy-2-naphthoic acid.

<18> The liquid crystal polymer film according to any one of <1> to <5> or <8> to <17>,

in which the liquid crystal polymer has at least one selected from the group consisting of a repeating unit derived from 6-hydroxy-2-naphthoic acid, a repeating unit derived from an aromatic diol compound, a repeating unit derived from terephthalic acid, and a repeating unit derived from 2,6-naphthalenedicarboxylic acid.

<19> The liquid crystal polymer film according to any one of <1> to <5> or <8> to <18>, further comprising:

a polyolefin,

in which a content of the polyolefin is 40% by mass or less with respect to a total mass of the liquid crystal polymer film.

According to the embodiment of the present disclosure, a liquid crystal polymer film having high tear resistance and excellent film-forming properties, a flexible copper-clad laminated board, and a manufacturing method of a liquid crystal polymer film are provided.

### DESCRIPTION OF THE PREFERRED EMBODIMENTS

Hereinafter, the liquid crystal polymer film, flexible copper-clad laminated board, and manufacturing method of a liquid crystal polymer film according to the embodiments of the present disclosure will be described in detail.

The present disclosure is not limited in any way to the following embodiments, and may be implemented with appropriate modifications within the scope of the purpose of the present disclosure.

In the present disclosure, the numerical ranges shown using “to” indicate ranges including the numerical values described before and after “to” as the lower limit value and the upper limit value. Regarding numerical ranges that are described stepwise in the present disclosure, an upper limit value or a lower limit value described in a numerical range may be replaced with an upper limit value or a lower limit value of another stepwise numerical range. In addition, in the numerical ranges described in the present disclosure, an upper limit value and a lower limit value disclosed in a certain range of numerical values may be replaced with values shown in Examples.

In the present disclosure, the amount of each component in a composition means, in a case where the composition contains a plurality of substances corresponding to such a component, the total amount of the plurality of substances in the composition, unless otherwise specified.

Regarding a term, group (atomic group) of this present disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In the present disclosure, “(meth)acrylic” means either or both of acrylic and methacrylic.

In the present disclosure, in a case where a liquid crystal polymer film has an elongated shape, a first direction means a width direction (lateral direction, TD direction) of the liquid crystal polymer film, and a second direction means a longitudinal direction (MD direction) of the liquid crystal polymer film.

In the present disclosure, a combination of two or more preferred aspects is a more preferred aspect.

<Liquid Crystal Polymer Film>

The liquid crystal polymer film according to the embodiment of the present disclosure includes a liquid crystal polymer, in which the liquid crystal polymer film has a melting point of 315° C. or higher and has a number-average molecular weight of 13,000 or more and 150,000 or less.

With the above-described configuration, the liquid crystal polymer film according to the embodiment of the present disclosure has high tear resistance and excellent film-forming properties. The reason is presumed as follows.

In a polymer film including a liquid crystal polymer, a polymer film having a high melting point (for example, a polymer film having a melting point of 315° C. or higher) may have low tear resistance or deteriorated film-forming properties. In order to increase the tear resistance of the polymer film having a high melting point, it is necessary to increase a molecular weight of the polymer. However, in a case where the molecular weight of the polymer is increased, the film-forming properties may be lowered. Here, the fact that the film-forming properties are lowered means that, for example, in a case where the polymer film is manufactured by a melt extrusion method, film breakage or holes occur in the polymer film during extrusion to form the polymer film.

On the other hand, the liquid crystal polymer film according to the embodiment of the present disclosure includes a liquid crystal polymer, and has a melting point of 315° C. or higher. Moreover, the liquid crystal polymer film according to the embodiment of the present disclosure has a number-average molecular weight of 13,000 or more and 150,000 or less. By setting the number-average molecular weight of the liquid crystal polymer film according to the embodiment of the present disclosure to 13,000 or more, the tear resistance of the polymer film can be enhanced. In addition, by setting the number-average molecular weight of the liquid crystal polymer film according to the embodiment of the present disclosure to 150,000 or less, the film-forming properties of the polymer film are excellent.

From the above, it is presumed that the liquid crystal polymer film according to the embodiment of the present disclosure has high tear resistance and excellent film-forming properties.

(Liquid Crystal Polymer)

The liquid crystal polymer includes a thermotropic liquid crystal polymer which exhibits liquid crystallinity in a molten state and a rheotropic liquid crystal polymer which exhibits liquid crystallinity in a solution state.

The liquid crystal polymer may by in any form as long as it is a melt-moldable liquid crystal polymer, but the thermotropic liquid crystal polymer is preferable.

Chemical composition of the thermotropic liquid crystal polymer is not particularly limited as long as it is a melt-moldable liquid crystal polymer. Examples of the thermotropic liquid crystal polymer include a thermoplastic liquid crystal polyester and a thermoplastic polyester amide with an amide bond introduced into the thermoplastic liquid crystal polyester.

As the liquid crystal polymer, a thermoplastic liquid crystal polymer described in WO2015/064437A can be used.

More specific examples of the liquid crystal polymer include a thermoplastic liquid crystal polyester or thermoplastic liquid crystal polyester amide having a repeating unit derived from at least one selected from the group consisting of an aromatic hydroxycarboxylic acid, an aromatic or aliphatic diol, an aromatic or aliphatic dicarboxylic acid, an aromatic diamine, an aromatic hydroxyamine, and an aromatic aminocarboxylic acid.

Examples of the aromatic hydroxycarboxylic acid include parahydroxybenzoic acid, metahydroxybenzoic acid, 6-hydroxy-2-naphthoic acid, and 4-(4-hydroxyphenyl)benzoic acid. These compounds may have substituents such as a halogen atom, a lower alkyl group, and a phenyl group. Among these, the parahydroxybenzoic acid or the 6-hydroxy-2-naphthoic acid is preferable.

As the aromatic or aliphatic diol, the aromatic diol is preferable. Examples of the aromatic diol include hydroquinone, 4,4′-dihydroxybiphenyl, 3,3′-dimethyl-1,1′-biphenyl-4,4′-diol, and acylated products thereof, and hydroquinone or 4,4′-dihydroxybiphenyl is preferable.

As the aromatic or aliphatic dicarboxylic acid, the aromatic dicarboxylic acid is preferable. Examples of the aromatic dicarboxylic acid include terephthalic acid, isophthalic acid, and 2,6-naphthalenedicarboxylic acid, and terephthalic acid is preferable.

Examples of the aromatic diamine, the aromatic hydroxyamine, and the aromatic aminocarboxylic acid include p-phenylenediamine, 4-aminophenol, and 4-aminobenzoic acid.

In addition, it is preferable that the liquid crystal polymer has at least one selected from the group consisting of the repeating units represented by Formulae (1) to (3).

—O-Ar1-CO— (1)

—CO-Ar2-CO— (2)

—X-Ar3-Y— (3)

In Formula (1), Ar1 represents a phenylene group, a naphthylene group, or a biphenylylene group.

In Formula (2), Ar2 represents a phenylene group, a naphthylene group, a biphenylylene group, or a group represented by Formula (4).

In Formula (3), Ar3 represents a phenylene group, a naphthylene group, a biphenylylene group, or the group represented by Formula (4), and X and Y each independently represent an oxygen atom or an imino group.

-Ar4-Z-Ar5- (4)

In Formula (4), Ar4 and Ar5 each independently represent a phenylene group or a naphthylene group, and Z represents an oxygen atom, a sulfur atom, a carbonyl group, a sulfonyl group, or an alkylene group.

The phenylene group, the naphthylene group, and the biphenylylene group may have a substituent selected from the group consisting of a halogen atom, an alkyl group, and an aryl group.

Among those, the liquid crystal polymer preferably has at least one selected from the group consisting of the repeating unit derived from an aromatic hydroxycarboxylic acid represented by Formula (1), the repeating unit derived from an aromatic diol represented by Formula (3), in which both X and Y are oxygen atoms, and the repeating unit derived from an aromatic dicarboxylic acid represented by Formula (2).

In addition, the liquid crystal polymer more preferably has at least a repeating unit derived from an aromatic hydroxycarboxylic acid, still more preferably has at least one selected from the group consisting of the repeating unit derived from parahydroxybenzoic acid and the repeating unit derived from 6-hydroxy-2-naphthoic acid, and particularly preferably has the repeating unit derived from parahydroxybenzoic acid and the repeating unit derived from 6-hydroxy-2-naphthoic acid.

In addition, as another preferred aspect, from the viewpoint that the effect of the present disclosure is more excellent, the liquid crystal polymer preferably has at least one selected from the group consisting of a repeating unit derived from 6-hydroxy-2-naphthoic acid, a repeating unit derived from an aromatic diol, a repeating unit derived from terephthalic acid, and a repeating unit derived from a 2,6-naphthalenedicarboxylic acid; and more preferably has all of a repeating unit derived from 6-hydroxy-2-naphthoic acid, a repeating unit derived from an aromatic diol, a repeating unit derived from terephthalic acid, and a repeating unit derived from 2,6-naphthalenedicarboxylic acid.

In a case where the liquid crystal polymer includes the repeating unit derived from an aromatic hydroxycarboxylic acid, a compositional ratio thereof is preferably 50% to 65% by mole with respect to all the repeating units of the liquid crystal polymer. In addition, it is also preferable that the liquid crystal polymer has only the repeating unit derived from an aromatic hydroxycarboxylic acid.

In a case where the liquid crystal polymer includes the repeating unit derived from an aromatic diol, a compositional ratio thereof is preferably 17.5% to 25% by mole with respect to all the repeating units of the liquid crystal polymer.

In a case where the liquid crystal polymer includes the repeating unit derived from an aromatic dicarboxylic acid, a compositional ratio thereof is preferably 11% to 23% by mole with respect to all the repeating units of the liquid crystal polymer.

In a case where the liquid crystal polymer includes the repeating unit derived from any of an aromatic diamine, an aromatic hydroxyamine, and an aromatic aminocarboxylic acid, a compositional ratio thereof is preferably 2% to 8% by mole with respect to all the repeating units of the liquid crystal polymer.

In a case where the liquid crystal polymer is a polymer including a constitutional unit derived from p-hydroxybenzoic acid and a constitutional unit derived from 6-hydroxy-2-naphthoic acid, a molar ratio ((A)/(B)) of the constitutional unit (A) derived from p-hydroxybenzoic acid to the constitutional unit (B) derived from 6-hydroxy-2-naphthoic acid is preferably 10/90 to 90/10, more preferably 50/50 to 85/15, and still more preferably 60/40 to 80/20.

Commercially available products may be used as the liquid crystal polymer, and examples thereof include “LAPEROS (product name)” manufactured by Polyplastics Co., Ltd., “VECTRA” manufactured by Celanese Corporation, “UENO LCP” manufactured by Ueno Fine Chemicals Industry, Ltd., “SUMIKA SUPER LCP” manufactured by Sumitomo Chemical Co., Ltd., “Xydar” manufactured by ENEOS LC Co., Ltd., and “Siveras” manufactured by Toray Industries, Inc.

The liquid crystal polymer may form a chemical bond in the liquid crystal polymer film with a crosslinking agent, a compatible component (reactive compatibilizer), or the like which is an optional component. The same applies to components other than the liquid crystal polymer.

From the viewpoint that a liquid crystal polymer film having a low standard dielectric loss tangent (preferably 0.0025 or less) can be easily manufactured, a standard dielectric loss tangent of the liquid crystal polymer is preferably 0.0022 or less, more preferably 0.0015 or less, and still more preferably 0.0010 or less. The lower limit value thereof is not particularly limited, and may be, for example, 0.0001 or more.

In a case where the liquid crystal polymer film includes two or more kinds of liquid crystal polymers, the “dielectric loss tangent of the liquid crystal polymer” means a mass-average value of dielectric loss tangents of the two or more kinds of liquid crystal polymers.

The standard dielectric loss tangent of the liquid crystal polymer included in the liquid crystal polymer film can be measured by the following method.

First, after performing immersion in an organic solvent (for example, pentafluorophenol) in an amount of 1,000 times by mass with respect to the total mass of the liquid crystal polymer film, the mixture is heated at 120° C. for 12 hours to elute organic solvent-soluble components including the liquid crystal polymer into the organic solvent. Next, the eluate including the liquid crystal polymer and the non-eluted components are separated by filtration. Subsequently, acetone is added to the eluate as a poor solvent to precipitate a liquid crystal polymer, and the precipitate is separated by filtration.

A standard dielectric loss tangent of the liquid crystal polymer can be obtained by filling a polytetrafluoroethylene (PTFE) tube (outer diameter: 2.5 mm, inner diameter: 1.5 mm, length: 10 mm) with the obtained precipitate; measuring dielectric characteristics by a cavity resonator perturbation method under the conditions of a temperature of 23° C. and a frequency of 28 GHz, using a cavity resonator (for example, “CP-531” manufactured by Kanto Electronics Application & Development, Inc.); and correcting influence of voids in the PTFE tube by a Bruggeman equation and a void ratio.

The void ratio (volume fraction of voids in the tube) is calculated as follows. A volume of a space inside the tube is determined from the inner diameter and the length of the tube described above. Next, weights of the tube before and after filling the precipitate are measured to determine a mass of the filled precipitate, and then a volume of the filled precipitate is determined from the obtained mass and a specific density of the precipitate. The void ratio can be calculated by dividing the volume of the precipitate thus obtained by the volume of the space in the tube determined above to calculate a filling rate.

In a case where a commercially available product of the liquid crystal polymer is used, a numerical value of the dielectric loss tangent of the commercially available product, described as a catalog value, may be used.

As for the liquid crystal polymer, from the viewpoint that the heat resistance is more excellent, a melting point Tm is preferably 250° C. or higher, more preferably 280° C. or higher, and still more preferably 310° C. or higher.

The upper limit value of the melting point Tm of the liquid crystal polymer is not particularly limited, but from the viewpoint that the moldability is more excellent, it is preferably 400° C. or lower and more preferably 380° C. or lower.

The melting point Tm of the liquid crystal polymer can be determined by measuring a temperature at which an endothermic peak appears, using a differential scanning calorimeter (“DSC-60A” manufactured by Shimadzu Corporation). In a case where a commercially available product of the liquid crystal polymer is used, the melting point Tm of the commercially available product described as a catalog value may be used.

A number-average molecular weight (Mn) of the liquid crystal polymer is not particularly limited, but is preferably 10,000 to 600,000 and more preferably 30,000 to 150,000.

The number-average molecular weight of the liquid crystal polymer is a value in terms of standard polystyrene, as measured by a gel permeation chromatography (GPC).

The measurement of GPC can be carried out with the following device and conditions.

“HLC (registered trademark)-8320GPC” manufactured by Tosoh Corporation is used as a measuring device, and two TSKgel (registered trademark) SuperHM-H's (6.0 mm ID×15 cm, manufactured by Tosoh Corporation) are used as a column. A solvent (eluent) for dissolving the liquid crystal polymer is not particularly limited, and examples thereof include a mixed solution of pentafluorophenol/chloroform=½ (mass ratio). The measurement conditions are as follows: a sample concentration of 0.03% by mass, a flow rate of 0.6 ml/min, a sample injection amount of 20 μL, and a measurement temperature of 40° C. Detection is performed using a differential refractometry (RI) detector.

A calibration curve is created using 8 samples of “F-40”, “F-20”, “F-4”, “F-1”, “A-5000”, “A-2500”, “A-1000”, and “n-propylbenzene” which are “Standard Samples TSK standard, polystyrene” (manufactured by TOSOH Corporation).

The liquid crystal polymer film may include one kind of liquid crystal polymer alone, or may include two or more kinds of liquid crystal polymers.

A content of the liquid crystal polymer is preferably 40% by mass to 100% by mass, more preferably 60% by mass to 99% by mass, and particularly preferably 80% by mass to 97% by mass with respect to the total mass of the liquid crystal polymer film. The content of the liquid crystal polymer and components in the liquid crystal polymer film, which will be described later, can be measured by a known method such as infrared spectroscopy and gas chromatography mass spectrometry.

(Other Components)

The liquid crystal polymer film may include a component other than the liquid crystal polymer. Examples of other components include an inorganic filler, a polymer other than the liquid crystal polymer, a crosslinking component, a compatible component, a plasticizer, a stabilizer, a lubricant, and a colorant.

—Inorganic Filler—

The inorganic filler is not particularly limited, and examples thereof include talc, mica, aluminum oxide, titanium oxide, silicon oxide, silicon nitride, and carbon black.

A shape of the inorganic filler is not particularly limited, and examples thereof include a spherical shape, a plate shape, a rod shape, a needle shape, and an indefinite shape. In addition, an average particle diameter (volume average particle size) of the inorganic filler is not particularly limited, but is preferably 0.050 μm to 10 μm.

A content of the inorganic filler is preferably 0.5% by mass or more, more preferably 1% by mass or more, and still more preferably 1.5% by mass or more with respect to the total mass of the liquid crystal polymer film. The upper limit value of the content of the inorganic filler is preferably 20% by mass or less, and more preferably 15% by mass or less with respect to the total mass of the liquid crystal polymer film.

—Polymer Other than Liquid Crystal Polymer—

Examples of the polymer other than the liquid crystal polymer include a thermoplastic resin and an elastomer. The elastomer refers to a polymer compound exhibiting elastic deformation. That is, the elastomer corresponds to a polymer compound having a property of being deformed according to an external force in a case where the external force is applied and of being recovered to an original shape in a short time in a case where the external force is removed.

Examples of the thermoplastic resin include a polyurethane resin, a polyester resin, a (meth)acrylic resin, a polystyrene resin, a fluororesin, a polyimide resin, a fluorinated polyimide resin, a polyamide resin, a polyamideimide resin, a polyether imide resin, a cellulose acylate resin, a polyurethane resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

(Polyolefin)

The polyolefin may be the above-described thermoplastic polyolefin resin or a polyolefin elastomer described later, but is not limited thereto.

In the present specification, the “polyolefin” is intended to be a polymer having a repeating unit derived from an olefin.

The liquid crystal polymer film preferably includes the liquid crystal polymer and the polyolefin, and more preferably includes the liquid crystal polymer, the polyolefin, and the compatible component.

The polyolefin may be linear or branched. In addition, the polyolefin may have a cyclic structure such as a polycycloolefin.

Examples of the polyolefin include polyethylene, polypropylene (PP), polymethylpentene (TPX manufactured by Mitsui Chemicals, Inc., and the like), hydrogenated polybutadiene, a cycloolefin polymer (COP, Zeonor manufactured by ZEON Corporation, and the like), and a cycloolefin copolymer (COC, APEL manufactured by Mitsui Chemicals, Inc., and the like).

The polyethylene may be either high density polyethylene (HDPE) or low density polyethylene (LDPE). In addition, the polyethylene may be linear low density polyethylene (LLDPE).

The polyolefin may be a copolymer of an olefin and a copolymerization component other than the olefin, such as acrylate, methacrylate, styrene, and/or a vinyl acetate-based monomer.

Examples of the polyolefin as the above-described copolymer include a styrene-ethylene/butylene-styrene copolymer (SEBS). The SEBS may be hydrogenated.

However, from the viewpoint that the effect of the present disclosure is more excellent, it is preferable that a copolymerization ratio of the copolymerization component other than the olefin is small, and it is more preferable that the copolymerization component is not included. For example, a content of the above-described copolymerization component is preferably 0% to 40% by mass, and more preferably 0% to 5% by mass with respect to the total mass of the polyolefin.

In addition, the polyolefin is preferably substantially free of a reactive group described later, and a content of the repeating unit having the reactive group is preferably 0% to 3% by mass with respect to the total mass of the polyolefin.

As the polyolefin, polyethylene, COP, or COC is preferable, polyethylene is more preferable, and the low density polyethylene (LDPE) is still more preferable.

The polyolefin may be used alone or in combination of two or more kinds thereof.

In a case where the liquid crystal polymer film includes a polyolefin, from the viewpoint that surface properties of the liquid crystal polymer film are more excellent, a content thereof is preferably 0.1% by mass or more, and more preferably 5% by mass or more with respect to the total mass of the liquid crystal polymer film. The upper limit thereof is not particularly limited, but from the viewpoint that smoothness of the liquid crystal polymer film is more excellent, it is preferably 50% by mass or less, more preferably 40% by mass or less, and still more preferably 25% by mass or less with respect to the total mass of the liquid crystal polymer film. In addition, in a case where the content of the polyolefin is 50% by mass or less, a thermal deformation temperature thereof can be easily raised sufficiently and the solder heat resistance can be improved.

(Elastomer)

The elastomer is not particularly limited, and examples thereof include an elastomer including a repeating unit derived from styrene (polystyrene-based elastomer), a polyester-based elastomer, a polyolefin-based elastomer, a polyurethane-based elastomer, a polyamide-based elastomer, a polyacrylic elastomer, a silicone-based elastomer, and a polyimide-based elastomer. The elastomer may be a hydrogenated product.

Examples the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a polystyrene-poly(ethylene-butylene)-polystyrene triblock copolymer (SEBS), and a polystyrene-poly(ethylene/ethylene-propylene)-polystyrene triblock copolymer (SEEPS).

A content of the polymer other than the liquid crystal polymer is not particularly limited, but is preferably 0.5% by mass to 40% by mass and more preferably 1% by mass to 20% by mass with respect to the total mass of the liquid crystal polymer film.

—Crosslinking Component—

Examples of the crosslinking component include compounds having a reactive group, such as an epoxy group-containing ethylene copolymer (for example, an ethylene-glycidyl methacrylate copolymer, an ethylene-vinyl acetate-glycidyl methacrylate copolymer, an ethylene-methyl acrylate-glycidyl methacrylate copolymer, and poly(ethylene-glycidyl methacrylate)-graft-poly(acrylonitrile-styrene)), a bisphenol-type epoxy compound, and a carbodiimide compound.

A content of the crosslinking component is preferably 0% by mass to 50% by mass with respect to the total mass of the liquid crystal polymer film.

—Compatible Component—

Examples of the compatible component include oxazoline-based compatibilizers (for example, a bisoxazoline-styrene-maleic acid anhydride copolymer, a bisoxazoline-maleic acid anhydride-modified polyethylene, and a bisoxazoline-maleic acid anhydride-modified polypropylene); elastomer-based compatibilizers (for example, a styrene-ethylene-butadiene copolymer, a styrene-ethylene-butadiene-styrene copolymer, a hydrogenated styrene-isopropylene-styrene copolymer, an aromatic resin, and a petroleum resin); reactive compatibilizers (for example, an ethylene glycidyl methacrylate copolymer, an ethylene maleic acid anhydride ethyl acrylate copolymer, ethylene glycidyl methacrylate-acrylonitrile styrene, acid-modified polyethylene wax, a COOH-modified polyethylene graft polymer, and a COOH-modified polypropylene graft polymer); and copolymer-based compatibilizers (for example, a polyethylene-polyamide graft copolymer, a polypropylene-polyamide graft copolymer, a methyl methacrylate-butadiene-styrene resin, acrylonitrile-butadiene rubber, an ethylene vinyl acetate-polyvinyl chloride (EVA-PVC)-graft copolymer, a vinyl acetate-ethylene copolymer resin, an ethylene-α-olefin copolymer, a propylene-α-olefin copolymer, and a hydrogenated styrene-isopropylene-block copolymer).

In addition, as the compatible component, ionomer resins such as an ethylene-methacrylic acid copolymer ionomer, an ethylene-acrylic acid copolymer ionomer, a propylene-methacrylic acid copolymer ionomer, a butylene-acrylic acid copolymer ionomer, a propylene-acrylic acid copolymer ionomer, an ethylene-vinyl sulfonic acid copolymer ionomer, a styrene-methacrylic acid copolymer ionomer, a sulfonated polystyrene ionomer, a fluorine-based ionomer, a telechelic polybutadiene acrylic acid ionomer, a sulfonated ethylene-propylene-diene copolymer ionomer, hydrogenated polypentamer ionomer, a polypentamer ionomer, a poly(vinylpyridium salt) ionomer, a poly(vinyltrimethylammonium salt) ionomer, a poly(vinyl benzyl phosphonium salt) ionomer, a styrene-butadiene acrylic acid copolymer ionomer, a polyurethane ionomer, a sulfonated styrene-2-acrylamide-2-methyl propane sulfate ionomer, an acid-amine Ionomer, an aliphatic ionene, and an aromatic ionene may be used.

A content of the compatible component is preferably 0% by mass to 50% by mass with respect to the total mass of the liquid crystal polymer film.

—Plasticizer, Stabilizer, Lubricant, and Organic Fine Particles—

Examples of the plasticizer include alkylphthalylalkyl glycolates, phosphoric acid esters, carboxylic acid esters, and polyhydric alcohols. A content of the plasticizer is preferably 0% by mass to 20% by mass with respect to the total mass of the liquid crystal polymer film.

Examples of the stabilizer include phosphite-based stabilizers (for example, tris(4-methoxy-3,5-diphenyl) phosphite, tris(nonylphenyl) phosphite, and tris(2,4-di-t-butylphenyl) phosphite), phenol-based stabilizers (for example, 2,6-di-t-butyl-4-methylphenol, 2,2-methylenebis(4-ethyl-6-t-butylphenol), 2,5-di-t-butylhydroquinone, pentaerythritol tetrakis[3-(3,5-di-t-butyl-4-hydroxyphenyl)propionate], 4,4-thiobis-(6-t-butyl-3-methylphenol), 1,1-bis(4-hydroxyphenyl)cyclohexane, and octadecyl-3-(3,5-di-t-butyl-4-hydroxyphenyl)propionate, epoxy compounds, and thioether compounds. A content of the stabilizer is preferably 0% by mass to 10% by mass with respect to the total mass of the liquid crystal polymer film.

Examples of the lubricant include a fatty acid ester and a metal soap (for example, a stearic acid inorganic salt). A content of the lubricant is preferably 0% by mass to 5% by mass with respect to the total mass of the liquid crystal polymer film.

Examples of the organic fine particles include organic fine particles such as crosslinked acrylic and crosslinked styrene. A content of the organic fine particles is preferably 0% by mass to 50% by mass with respect to the total mass of the liquid crystal polymer film.

(Melting Point)

The liquid crystal polymer film according to the embodiment of the present disclosure has a melting point of 315° C. or higher.

By setting the melting point of the liquid crystal polymer film to 315° C. or higher, a liquid crystal polymer film capable of withstanding processing accompanied by heating, such as soldering, is obtained.

From the viewpoint of obtaining a liquid crystal polymer film capable of withstanding processing accompanied by heating, such as soldering, the lower limit value of the melting point of the liquid crystal polymer film is preferably 320° C. or higher, more preferably 322° C. or higher, and still more preferably 324° C. or higher.

In a case where the melting point of the liquid crystal polymer film is too high (for example, the melting point is 360° C. or higher), processing at a high temperature may be required in the manufacturing of the liquid crystal polymer film. In this case, a manufacturing facility capable of processing at a high temperature is separately required, which may increase manufacturing cost. From the viewpoint of suppressing the manufacturing cost of the liquid crystal polymer film, the upper limit value of the melting point of the liquid crystal polymer film may be 360° C. or lower.

The melting point of the liquid crystal polymer film is a value measured under the following conditions using a differential scanning calorimeter. The melting point of the liquid crystal polymer film can be measured using, for example, DSC-50 (manufactured by Shimadzu Corporation).

<Conditions>
Atmosphere in measurement room: nitrogen
Temperature increase rate: 20° C./min
Measurement start temperature: 25° C.
Mass of measurement sample: 8 mg

(Number-Average Molecular Weight)

The liquid crystal polymer film according to the embodiment of the present disclosure has a number-average molecular weight of 13,000 or more and 150,000 or less.

By setting the number-average molecular weight of the liquid crystal polymer film within the above-described range, a liquid crystal polymer film having high tear resistance and excellent film-forming properties is obtained.

From the viewpoint of obtaining a liquid crystal polymer film having high tear resistance and excellent film-forming properties, the number-average molecular weight of the liquid crystal polymer film is preferably 18,000 or more and 150,000 or less, more preferably 18,500 or more and 130,000 or less, still more preferably 19,000 or more and 100,000 or less, even more preferably 19,000 or more and 35,000 or less, particularly preferably 19,000 or more and 30,000 or less, and most preferably 20,000 or more and 25,000 or less.

The number-average molecular weight of the liquid crystal polymer film is measured by a gel permeation chromatography (GPC) analysis apparatus. Measurement conditions are as follows, for example.

<Conditions>
Column: TSKgel SuperHM-H (product name manufactured by Tosoh Corporation)
Solvent: pentafluorophenol (PFP)/chloroform=½ (mass ratio)
Standard substance: polystyrene

(Melt Viscosity)

In the liquid crystal polymer film according to the embodiment of the present disclosure, it is preferable that a melt viscosity in a case where a temperature is set to be higher than the melting point by 5° C. and a shear rate is set to be 1000 sec⁻¹ is 80 Pa·s or more and 400 Pa·s or less.

In a case where the melt viscosity of the liquid crystal polymer film satisfies the above-described condition, it is easy to obtain a liquid crystal polymer film having further high tear resistance and excellent film-forming properties.

The reason is presumed as follows.

For example, in manufacturing of the liquid crystal polymer film by a melt extrusion method, in a case where the melt viscosity satisfies the above-described condition, a liquid crystal polymer film having a large molecular weight is likely to be uniformly extruded during the extrusion film formation. Therefore, in a case where the melt viscosity satisfies the above-described condition, it is easy to obtain a liquid crystal polymer film having a large molecular weight in a state in which film breakage or occurrence of holes is suppressed.

From the above, in a case where the melt viscosity of the liquid crystal polymer film satisfies the above-described condition, it is presumed that it is easy to obtain the liquid crystal polymer film having further high tear resistance and excellent film-forming properties.

In the liquid crystal polymer film, from the viewpoint of obtaining a liquid crystal polymer film having further high tear resistance and excellent film-forming properties, it is more preferable that the melt viscosity in a case where a temperature is set to be higher than the melting point of the liquid crystal polymer film by 5° C. and a shear rate is set to be 1000 sec⁻¹ is 90 Pa·s or more and 350 Pa·s or less, and it is still more preferable to be 100 Pa·s or more and 300 Pa·s or less.

The melt viscosity is a value measured by an apparent melt viscosity in accordance with ISO 11443 (1995), in which a cylinder temperature of a capillary type rheometer is set to a temperature higher than a melting point of a sample by 5° C. and a shear rate is set to 1000 sec⁻¹. The melt viscosity can be measured using, for example, a capillary type rheometer (manufactured by Toyo Seiki Seisaku-sho, Ltd, product name: Capilograph 1D, barrel inner diameter: 9.55 mm). In this case, an orifice having an inner diameter of 1 mm and a length of 10 mm is used for the measurement.

The melting point of the sample is measured under the same conditions as the measurement of the melting point of the liquid crystal polymer film described above.

(Amount of Heat of Crystal Melting)

In the liquid crystal polymer film according to the embodiment of the present disclosure, it is preferable that an amount of heat of crystal melting, which is determined by a differential scanning calorimetry, (hereinafter, also simply referred to as a “heat of crystal melting”) is 2 J/g or less.

By setting the amount of heat of crystal melting of the liquid crystal polymer film within the above-described range, it is easy to obtain a liquid crystal polymer film having further excellent film-forming properties.

The reason is presumed as follows.

By setting the amount of heat of crystal melting of the liquid crystal polymer film to 2 J/g or less, in a case where the liquid crystal polymer film is melted, the number of crystal components tends to be small. This indicates that, for example, in a case of manufacturing of the liquid crystal polymer film by a melt extrusion method, the liquid crystal polymer film tends to be uniformly extruded during the extrusion film formation. Therefore, in a case where the amount of heat of crystal melting satisfies the above-described condition, it is easy to obtain a liquid crystal polymer film with suppressed film breakage or occurrence of holes.

From the above, in a case where the amount of heat of crystal melting of the liquid crystal polymer film satisfies the above-described condition, it is presumed that it is easy to obtain the liquid crystal polymer film having further excellent film-forming properties.

From the viewpoint of obtaining a liquid crystal polymer film having further excellent film-forming properties, the amount of heat of crystal melting of the liquid crystal polymer film is preferably 0.05 J/g or more and 1.5 J/g or less, more preferably 0.1 J/g or more and 1.0 J/g or less, and still more preferably 0.3 J/g or more and 0.8 J/g or less.

The amount of heat of crystal melting of the liquid crystal polymer film is a value measured using a differential scanning calorimeter, and can be measured using, for example, DSC-50 (manufactured by Shimadzu Corporation). Measurement conditions are the same as the measurement of the melting point of the liquid crystal polymer film described above.

The melting point of the liquid crystal polymer film is measured under the conditions described in the measurement of the melting point of the liquid crystal polymer above. The amount of heat of crystal melting is calculated from heat absorption peaks in a temperature range of (the melting point of the liquid crystal polymer film)−30° C. to (the melting point of the liquid crystal polymer film)+30° C.

A thickness of the liquid crystal polymer film is preferably 5 μm to 1100 μm, more preferably 5 μm to 1000 μm, still more preferably 5 μm to 250 μm, and particularly preferably μm to 150 μm.

A method for measuring the thickness of the liquid crystal polymer film is as shown in Examples described later.

[Elastic Modulus Characteristics]

In the liquid crystal polymer film according to the embodiment of the present disclosure, it is preferable that, in a cross section of the liquid crystal polymer film along a thickness direction of the liquid crystal polymer film, in a case where an elastic modulus at a position A at a distance of half of a thickness of the liquid crystal polymer film from one surface toward the other surface of the liquid crystal polymer film is defined as an elastic modulus A and an elastic modulus at a position B at a distance of ⅛ of the thickness of the liquid crystal polymer film from one surface toward the other surface of the liquid crystal polymer film is defined as an elastic modulus B, a ratio B/A (hereinafter, also referred to as a “specific elastic modulus ratio”) of the elastic modulus B to the elastic modulus A is 0.99 or less and the elastic modulus A is 4.0 GPa or more.

In a case where the liquid crystal polymer film including a liquid crystal polymer has a predetermined specific elastic modulus ratio and elastic modulus A, adhesiveness between the liquid crystal polymer film and a metal foil in a laminate is excellent, and the performance of suppressing a misregistration of a wiring line formed on the metal foil is excellent even in a case of further laminating a sticking material to the wiring line. The mechanism is not clear, but the present inventors presume as follows. That is, it is presumed that, in a case where the elastic modulus A at the center in the thickness direction of the liquid crystal polymer film is equal to or higher than a predetermined value, a relative displacement of the metal-containing layers arranged on both surfaces of the liquid crystal polymer film in the in-plane direction is suppressed, and the misregistration of the wiring line in the in-plane direction is easily prevented even upon sticking another laminate onto the wiring line. In addition, it is presumed that, in a case where the specific elastic modulus ratio is equal to or less than a predetermined value, the elastic modulus of the liquid crystal polymer film as a whole is maintained, but the elastic modulus is relatively lowered at the position B near the surface layer, and as a result, the adhesiveness with the metal-containing layer stuck to the liquid crystal polymer film is easily improved. In this manner, it is considered that a liquid crystal polymer film, in which the adhesiveness between the liquid crystal polymer film and a metal foil in a laminate is excellent, and the performance of suppressing a misregistration of a wiring line formed on the metal foil is excellent even in a case of further laminating a sticking material to the wiring line, is obtained.

In the present specification, with regard to a laminate produced by sticking a metal foil onto a liquid crystal polymer film, a case where the adhesiveness between the liquid crystal polymer film and the metal foil is more excellent, and/or the performance of suppressing a misregistration of a wiring line formed on the metal foil is more excellent in a case of further laminating a sticking material to the wiring line is also described as “the effect of adhesiveness and/or suppressing misregistration of a wiring line is more excellent”.

From the viewpoint that the effect of adhesiveness and/or misregistration of a wiring line is more excellent, the elastic modulus A at the position A of the liquid crystal polymer film is preferably 4.3 GPa or more, and more preferably 4.6 GPa or more. The upper limit value thereof is not particularly limited, but is, for example, 5.0 GPa or less.

In addition, from the viewpoint that the effect of adhesiveness and/or misregistration of a wiring line is more excellent, the specific elastic modulus ratio which is the ratio B/A of the elastic modulus B to the elastic modulus A is preferably 0.99 or less, more preferably 0.98 or less, and still more preferably 0.96 or less. The lower limit value thereof is not particularly limited, but from the viewpoint of suppressing the misregistration in a case of laminating a sticking material, it is preferably 0.80 or more and more preferably 0.85 or more. From the viewpoint that the effect of adhesiveness and/or misregistration of a wiring line is more excellent, the elastic modulus B at the position B of the liquid crystal polymer film is preferably 3.7 to 4.95 GPa, and more preferably 3.9 to 4.8 GPa.

The elastic modulus in the cross section of the liquid crystal polymer film is an indentation elastic modulus measured using a nanoindenter according to IS014577, and a specific measuring method therefor will be described in Examples later.

The elastic moduli (elastic moduli A and B) of the liquid crystal polymer film can be adjusted by, for example, subjecting the liquid crystal polymer film to a heat treatment and/or a cooling treatment at a temperature higher than the melting point Tm of the liquid crystal polymer in the film forming step, changing the conditions (a heating temperature, a cooling rate, and the like), and controlling the alignment in the thickness direction and the crystallized structure of the liquid crystal polymer film.

The specific elastic modulus ratio of the liquid crystal polymer film can be adjusted by, for example, carrying out a specific heat treatment described later in the film forming step for the liquid crystal polymer film, or by subjecting the liquid crystal polymer film after manufacturing to heating and cooling in the same manner as the specific heat treatment described later to control the alignment in the thickness direction and the crystallized structure of the liquid crystal polymer film.

[Void Characteristics]

In the liquid crystal polymer film according to the embodiment of the present disclosure, it is preferable that, in a case where a cross section of the liquid crystal polymer film along a thickness direction of the liquid crystal polymer film is exposed and immersed in monomethylamine, and then void regions are extracted from an observed image of the cross section, obtained by using an electron microscope, an average value of widths of the void regions is 0.01 to 0.1 μm and an area ratio (void region area ratio) of the void regions in the observed image of the cross section is 20% or less.

It is considered that, in a case where the liquid crystal polymer film including a liquid crystal polymer satisfies the above-described requirement regarding the voids present in the cross section including the thickness direction, in a metal-clad laminated board produced by laminating the liquid crystal polymer film and the metal foil, peel strength of the metal foil is improved by suppressing a cohesive failure in the liquid crystal polymer film during peeling off the metal foil from the liquid crystal polymer film.

The mechanism for improving the peel strength of the metal foil is not clear, but the present inventors presume as follows. That is, in a case where voids in the cross section in the thickness direction satisfy the above-described requirement, a space occupied by a substantial part (domain region) composed of the liquid crystal polymer and the like is large and a space occupied by the voids is small in the liquid crystal polymer film, and further, it is considered that since a distance between the domain regions in the thickness direction is narrow, an adhesive force or cohesive force between the domain regions is increased, and as a result, a cohesive failure in the liquid crystal polymer film upon the peeling of the metal foil from the liquid crystal polymer film in a metal-clad laminate produced by laminating the metal foil is suppressed and the peel strength of the metal foil is improved.

Hereinafter, in the present specification, a case where the peel strength is more excellent in a laminate manufactured by sticking the liquid crystal polymer film and the metal foil to each other is also described as “the peel strength is more excellent”.

In the present specification, the “void region” is a region in which voids observed in an image obtained by using an electron microscope with a cross section of the liquid crystal polymer film along the thickness direction of the liquid crystal polymer film by a predetermined method are present. The area and the size of the void region can be determined based on data obtained by processing a captured image processing with image processing software (ImageJ) after imaging a cross-section exposed by cutting the liquid crystal polymer film along the thickness direction, using a scanning electron microscope (SEM). A specific measuring method therefor will be described in Examples later.

The void region area ratio of the liquid crystal polymer film according to the embodiment of the present disclosure is preferably 20% or less. From the viewpoint that the peel strength is more excellent, the void region area ratio of the liquid crystal polymer film is more preferably 15% or less and still more preferably 10% or less. The lower limit value thereof is not particularly limited, and is, for example, 0.1% or more.

In addition, in the liquid crystal polymer film according to the embodiment of the present disclosure, an average width of the void regions is preferably 0.01 to 0.1 μm. From the viewpoint that the effect of peel strength is more excellent, the average width of the void regions is more preferably 0.02 to 0.05 μm.

From the viewpoint that adhesion between domain layers is more excellent, an average length of the void regions of the liquid crystal polymer film is preferably 0.5 to 10 μm, more preferably 1.0 to 8.0 μm, and still more preferably 3 to 5 μm.

The void region area ratio in the cross section in the thickness direction of the liquid crystal polymer film, and the average width and the average length of the void regions can be adjusted by, for example, carrying out an annealing treatment described later in the film forming step for the liquid crystal polymer film.

In the liquid crystal polymer film, from the viewpoint that the peel strength is more excellent, it is preferable that a thickness of the liquid crystal polymer film is 15 μm or more and satisfies Requirement A.

Requirement A: in the cross section in the thickness direction, in a case where a region where a distance from one surface of the liquid crystal polymer film is within 5 μm is defined as a first surface layer region, a region where a distance from the other surface of the liquid crystal polymer film is within 5 μm is defined as a second surface layer region, and a region within 2.5 μm from a center line equidistant from both surfaces of the liquid crystal polymer film is defined as a central layer region, an area ratio of void regions in the central layer region is higher than an area ratio of void regions in the first surface layer region and is also higher than an area ratio of void regions in the second surface layer region.

From the viewpoint that the peel strength is more excellent, a proportion of the void region area ratio in the central layer region to the void region area ratio in the first surface layer region and the second surface layer region (hereinafter the both are collectively referred to as a “surface layer region”) is preferably 120% or more, and more preferably 150% or more. The upper limit value thereof is, for example, 300% or less, preferably 200% or less.

The void region area ratio in the surface layer region varies depending on the void region area ratio of the entire thickness direction, but is, for example, 0.1% to 30%, preferably 0.1% to 20%.

The void region area ratio in the central layer region varies depending on the void region area ratio in the entire thickness direction, but is, for example, 0.1% to 30%, preferably 5% to 20%.

In the liquid crystal polymer film, the void region area ratios in the surface layer region and the central layer region can be adjusted by, for example, carrying out a specific heat treatment described later in the film forming step for the liquid crystal polymer film.

In the liquid crystal polymer film according to the embodiment of the present disclosure, it is preferable that, in a case where a hardness at a position A at a distance of half of a thickness of the liquid crystal polymer film from one surface toward the other surface of the liquid crystal polymer film is defined as a hardness A and a hardness at a position B at a distance of 1/10 of the thickness of the liquid crystal polymer film from one surface toward the other surface of the liquid crystal polymer film is defined as a hardness B, the hardness A and the hardness B satisfy a relationship of Expression (1A). In addition, in the above-described cross section, it is preferable that, in a case where a position at the distance of 1/10 of the thickness of the liquid crystal polymer film from the one surface toward the other surface of the liquid crystal polymer film is defined as a position T1, a position at a distance of 4/10 of the thickness of the liquid crystal polymer film from the one surface toward the other surface of the liquid crystal polymer film is defined as a position T2, and a position at a distance of 6/10 of the thickness of the liquid crystal polymer film from the one surface toward the other surface of the liquid crystal polymer film is defined as a position T3, a region from the one surface to the position T1 is defined as an S region, and a region from the position T2 to the position T3 is defined as a C region, an area ratio of void regions in the S region is defined as a void area proportion X, and an area ratio of void regions in the C region is defined as a void area proportion Y, the void area proportion X and the void area proportion Y satisfy a relationship of Expression (2A).

(Hardness A+Hardness B)/2≥0.10 GPa Expression (1A)

Void area proportion Y−Void area proportion X≥0.10% Expression (2A)

In the liquid crystal polymer film according to the embodiment of the present disclosure, in a case where Expression (1A) and Expression (2A) are satisfied, the dielectric loss tangent is low, and a difference in linear expansion coefficiency with the copper foil tends to be small. Details of a reason thereof are not clear, but are usually presumed to be as follows.

A liquid crystal polymer film having a high hardness tends to exhibit a lower standard dielectric loss tangent. Here, Expression (1A) indicates a relationship between the hardness in the center of the thickness of the liquid crystal polymer film and the hardness in the surface layer part, and since the liquid crystal polymer film satisfying Expression (1A) can be said to have a high hardness of the entire film, it is presumed that the liquid crystal polymer film exhibits a low standard dielectric loss tangent.

Here, in a case where the liquid crystal polymer film is used in manufacturing of a circuit board, it is used in the form of a laminate having the liquid crystal polymer film and a copper foil. In this case, in a case where the difference in linear expansion coefficiency between the liquid crystal polymer film and the copper foil is decreased, there is an advantage in suppressing warping of the laminate during heating in a case where the liquid crystal polymer film has a high hardness, and in improving the adhesiveness between the liquid crystal polymer film and the copper foil.

The present inventors have found that the difference in linear expansion coefficiency with the copper foil can be decreased by using a liquid crystal polymer film satisfying Expression (2A) as well as Expression (1A).

Expression (2A) indicates a relationship between the void area proportion in the surface layer part of the liquid crystal polymer film and the void area proportion in the center of the thickness of the liquid crystal polymer film. A reason therefor is not clear, but it is considered that a liquid crystal polymer film having the void area proportions satisfying the relationship of Expression (2A) is controlled in stretching in the thickness direction and suppressed in expansion in the in-plane direction. As a result, it is presumed that, even in a case where a liquid crystal polymer film having a high hardness, satisfying Expression (1A), is used, the difference in linear expansion coefficiency with the copper foil is remarkably decreased by satisfying Expression (2A).

[Hardness]

In the liquid crystal polymer film according to the embodiment of the present disclosure, it is preferable that, in the cross section of the liquid crystal polymer film along the thickness direction of the liquid crystal polymer film, in a case where a hardness at a position A at a distance of half of a thickness of the liquid crystal polymer film from one surface toward the other surface of the liquid crystal polymer film is defined as a hardness A and a hardness at a position B at a distance of 1/10 of the thickness of the liquid crystal polymer film from one surface toward the other surface of the liquid crystal polymer film is defined as a hardness B, the hardness A and the hardness B satisfy a relationship of Expression (1A).

(Hardness A+Hardness B)/2≥0.10 GPa Expression (1A)

From the viewpoint of obtaining a liquid crystal polymer film having a lower dielectric loss tangent and a smaller difference in linear expansion coefficiency with the copper foil, the lower limit of “(Hardness A+Hardness B)/2” in Expression (1A) is preferably 0.12 GPa or more, more preferably 0.14 GPa or more, and still more preferably 0.16 GPa or more.

From the viewpoint of obtaining a liquid crystal polymer film having a lower dielectric loss tangent and a smaller difference in linear expansion coefficiency with the copper foil, the upper limit of “(Hardness A+Hardness B)/2” in Expression (1A) is preferably 0.30 GPa or less, more preferably 0.25 GPa or less, and still more preferably 0.20 GPa or less.

From the viewpoint of obtaining a liquid crystal polymer film having a lower dielectric loss tangent and a smaller difference in linear expansion coefficiency with the copper foil, it is preferable that the hardness A and the hardness B satisfy a relationship of Expression (1B).

(Hardness A−Hardness B)≥−0.02 GPa Expression (1B)

From the viewpoint of obtaining a liquid crystal polymer film having a lower dielectric loss tangent and a smaller difference in linear expansion coefficiency with the copper foil, the lower limit of “(Hardness A−Hardness B)” in Expression (1B) is preferably −0.01 GPa or more and more preferably 0.00 GPa or more.

From the viewpoint of obtaining a liquid crystal polymer film having a lower dielectric loss tangent and a smaller difference in linear expansion coefficiency with the copper foil, the upper limit of “(Hardness A−Hardness B)” in Expression (1B) is preferably 0.06 GPa or less, more preferably 0.04 GPa or less, and still more preferably 0.02 GPa or less.

From the viewpoint of obtaining a liquid crystal polymer film having a lower dielectric loss tangent and a smaller difference in linear expansion coefficiency with the copper foil, the hardness A is preferably 0.10 to 0.25 GPa, and more preferably 0.12 to 0.20 GPa. From the viewpoint of obtaining a liquid crystal polymer film having a lower dielectric loss tangent and a smaller difference in linear expansion coefficiency with the copper foil, the hardness B is preferably 0.12 to 0.30 GPa, and more preferably 0.14 to 0.25 GPa.

The hardness in the cross section of the liquid crystal polymer film is an indentation hardness measured using a nanoindenter according to IS014577, and a specific measuring method therefor will be described in Examples later.

In addition, the value of “(Hardness A+Hardness B)/2” in the liquid crystal polymer film can be adjusted by, for example, carrying out a specific heat treatment described later in the film forming step for the liquid crystal polymer film and controlling an amount of heat (temperature×time) related to an annealing treatment described later.

Moreover, the value of “(Hardness A−Hardness B)” in the liquid crystal polymer film can be adjusted by, for example, carrying out the specific heat treatment described later in the film forming step for the liquid crystal polymer film and controlling an amount of heat according to the thickness direction of the liquid crystal polymer film in the annealing treatment described later.

[Void Area Proportion]

In the liquid crystal polymer film according to the embodiment of the present disclosure, it is preferable that, in the cross section of the liquid crystal polymer film along the thickness direction of the liquid crystal polymer film, in a case where a position at the distance of 1/10 of the thickness of the liquid crystal polymer film from the one surface toward the other surface of the liquid crystal polymer film is defined as a position T1, a position at a distance of 4/10 of the thickness of the liquid crystal polymer film from the one surface toward the other surface of the liquid crystal polymer film is defined as a position T2, and a position at a distance of 6/10 of the thickness of the liquid crystal polymer film from the one surface toward the other surface of the liquid crystal polymer film is defined as a position T3, a region from the one surface to the position T1 is defined as an S region, and a region from the position T2 to the position T3 is defined as a C region, an area proportion of voids in the S region is defined as a void area proportion X, and an area proportion of voids in the C region is defined as a void area proportion Y, the void area proportion X and the void area proportion Y satisfy a relationship of Expression (2A).

Void area proportion Y−Void area proportion X≥0.10% Expression (2A)

From the viewpoint of obtaining a liquid crystal polymer film having a lower dielectric loss tangent and a smaller difference in linear expansion coefficiency with the copper foil, the lower limit of “Void area proportion Y−Void area proportion X” in Expression (2A) is preferably 0.20% or more and more preferably 0.30% or more.

From the viewpoint of obtaining a liquid crystal polymer film having a lower dielectric loss tangent and a smaller difference in linear expansion coefficiency with the copper foil, the upper limit of “Void area proportion Y−Void area proportion X” in Expression (2A) is preferably 0.70% or less, more preferably 0.60% or less, and still more preferably 0.50% or less.

From the viewpoint of obtaining a liquid crystal polymer film having a lower dielectric loss tangent and a smaller difference in linear expansion coefficiency with the copper foil, the void area proportion X is preferably 8% to 20% and more preferably 10% to 18%.

From the viewpoint of obtaining a liquid crystal polymer film having a lower dielectric loss tangent and a smaller difference in linear expansion coefficiency with the copper foil, the void area proportion Y is preferably 10% to 22% and more preferably 12% to 20%.

The void area proportion in each region of the cross section of the liquid crystal polymer film means a proportion (%) of the area of voids in each region with respect to the area of each region in the cross section of the liquid crystal polymer film. The void area proportion can be determined as follows: the liquid crystal polymer film cut so that a cross section in the thickness direction has been exposed is immersed in propylamine, then the cross section of the liquid crystal polymer film is imaged with a scanning electron microscope (SEM), and the captured image is subjected to image processing with image processing software (ImageJ) to obtain data, and the void area proportion can be determined based on the data. A specific measuring method therefor will be described in Examples later.

In addition, the values of the void area proportions (the void area proportions X and Y) and the “Void area proportion Y−Void area proportion X” in the liquid crystal polymer film can be adjusted by, for example, carrying out a specific heat treatment described later in the film forming step for the liquid crystal polymer film, controlling an amount of heat (temperature×time) in an annealing treatment described later, and controlling an amount of heat applied to the annealing treatment described later in the thickness direction of the liquid crystal polymer film.

(Layer Structure)

The liquid crystal polymer film may have a monolayer structure or a laminated structure in which a plurality of layers are laminated. The term “monolayer structure” of the liquid crystal polymer film means that the liquid crystal polymer film is composed of the same material over the entire thickness.

(Dielectric Characteristics)

A standard dielectric loss tangent of the liquid crystal polymer film is not particularly limited, but is, for example, 0.0025 or less, preferably 0.0024 or less, more preferably 0.0022 or less, still more preferably 0.0020 or less, particularly preferably 0.0015 or less, and most preferably 0.0010 or less. The lower limit value thereof is not particularly limited, and may be 0.0001 or more.

A relative permittivity of the liquid crystal polymer film varies depending on the application, but is preferably 2.0 to 4.0, and more preferably 2.5 to 3.5.

The dielectric characteristics including the standard dielectric loss tangent and the relative permittivity of the liquid crystal polymer film can be measured by a cavity resonator perturbation method. A specific method for measuring the dielectric characteristics of the liquid crystal polymer film will be described in the column of Examples later.

<Manufacturing Method of Liquid Crystal Polymer Film>

A manufacturing method of the liquid crystal polymer film according to the embodiment of the present disclosure is not particularly limited, but for example, preferably includes a pelletizing step of kneading each of the above-described components to obtain pellets, and a film forming step of obtaining the liquid crystal polymer film using the pellets obtained by the pelletizing step. In the following, the liquid crystal polymer film according to the embodiment of the present disclosure may be simply referred to as a “film”. Each step will be described below.

[Pelletizing Step]

(Pelletization)

The outline of the pelletization procedure is as follows.

First, the liquid crystal polymer and additives are melt-kneaded by a kneader. Subsequently, the melt-kneaded liquid crystal polymer and additives are cut, and then cooled and solidified to obtain pellets.

Details of the pelletization will be described below.

(1) Form of Raw Material

As the liquid crystal polymer used for the film formation, pellet-shaped, flake-shaped or powder-shaped ones can be used as they are, but for the purpose of stabilizing the film formation and uniformly dispersing an additive (meaning a component other than the liquid crystal polymer; the same applies hereinafter), it is preferable that one or more kinds of raw materials (meaning at least one of the liquid crystal polymer or additives; the same applies hereinafter) are pelletized with an extruder before use.

(2) Heat Treatment of Liquid Crystal Polymer

The liquid crystal polymer used for the film formation may be heat-treated as necessary for the purpose of adjusting the molecular weight of the liquid crystal polymer.

The heat treatment of the liquid crystal polymer refers to a treatment of stirring the liquid crystal polymer while heating the liquid crystal polymer.

In the heat treatment of the liquid crystal polymer, a temperature of the liquid crystal polymer is preferably 240° C. or higher and 360° C. or lower.

In the heat treatment of the liquid crystal polymer, a method for stirring the liquid crystal polymer is not particularly limited as long as the liquid crystal polymer is uniformly heated.

It is preferable that the heat treatment of the liquid crystal polymer is carried out until the number-average molecular weight of the liquid crystal polymer is 13,000 or more and 150,000 or less. The measurement of the number-average molecular weight of the liquid crystal polymer is performed in the same manner as the measurement of the number-average molecular weight of the liquid crystal polymer film described above.

A heat treatment time of the liquid crystal polymer is preferably 220 minutes or more and 1220 minutes or less.

(3) Drying or Drying Alternative by Vent

It is preferable that the liquid crystal polymer and the additives are dried before being pelletized. Examples of the drying method include a method of circulating a heated air having a low dew point and a method of dehumidifying by vacuum drying. In particular, in a case of drying a resin which is easily oxidized, the method of dehumidifying by vacuum drying is preferable. In addition, in a case of using the method of circulating a heated gas having a low dew point to dry a liquid crystal polymer which is easily oxidized, as the heated gas, it is preferable to use a heated inert gas.

In addition, the drying can be substituted with a method of using a vent type extruder. There are uniaxial and biaxial types of vent type extruders, and both can be used. From the viewpoint of work efficiency, it is preferable that the vent type extruder is a biaxial type. In a case of extruding the liquid crystal polymer and the additives using the vent type extruder, a pressure in the extruder is preferably set to less than 1 atm, more preferably 0 atm to 0.8 atm and still more preferably 0 atm to 0.6 atm. In order to set the pressure in the extruder to be within the above-described range, it can be achieved by exhausting air from a vent or hopper provided in a kneading portion of the extruder using a vacuum pump.

(4) Method for Supplying Raw Materials

A method for supplying raw materials may be a method in which raw materials are mixed in advance before being kneaded and then supplied into the extruder, a method in which raw materials are separately supplied into the extruder so as to be in a fixed proportion, or a method of a combination of the both.

(5) Type of Extruder

As the extruder, as long as a sufficient melt-kneading effect can be obtained, known uniaxial screw extruders, non-meshing different-direction rotating biaxial screw extruders, meshing different-direction rotating biaxial screw extruders, meshing co-rotating biaxial screw extruders, and the like can be used.

(6) Atmosphere during Extrusion

In the melt extrusion, it is preferable to prevent thermal deterioration and oxidative deterioration as much as possible within a range which does not hinder uniform dispersion. Therefore, it is preferable to reduce an oxygen concentration in the extruder. Examples of a method of reducing the oxygen concentration in the extruder include a method of reducing the pressure using a vacuum pump and a method of inflowing an inert gas. These methods may be carried out alone or in combination.

(7) Rotation Speed

A screw rotation speed of the extruder is preferably 10 revolutions per minutes (rpm; the same applies hereinafter) to 1000 rpm, more preferably 20 rpm to 700 rpm, and particularly preferably 30 rpm to 500 rpm. In a case where the rotation rate is set to the lower limit value or more, a retention time of the raw materials can be shortened, so that it is possible to suppress a decrease in molecular weight due to thermal deterioration and a remarkable coloration of the resin due to thermal deterioration. In addition, in a case where the rotation rate is set to the upper limit value or less, a breakage of a molecular chain due to shearing of the raw materials can be suppressed, so that it is possible to suppress a decrease in molecular weight and an increase in generation of crosslinked gel. It is preferable to select appropriate conditions for the screw rotation speed from the viewpoints of both uniform dispersibility and thermal deterioration due to extension of the retention time.

(8) Temperature

A kneading temperature is preferably set to be equal to or lower than a thermal decomposition temperature of the resin and the additive, and is preferably set to a low temperature as much as possible within a range in which a load of the extruder and a decrease in uniform kneading property are not a problem. However, in a case where the temperature is too low, the melt viscosity may increase, and conversely, a shear stress during kneading may increase, causing molecular chain breakage. Therefore, it is necessary to select an appropriate range. In addition, in order to achieve both improvement in dispersibility and suppression of thermal deterioration, it is also effective to melt and mix a first half part in the extruder at a relatively high temperature and lower the resin temperature in a second half part.

(9) Pressure

A kneading resin pressure during the pelletization is preferably 0.05 MPa to 30 MPa. In a case of a resin in which coloration or gel is likely to be generated due to shearing, it is preferable to apply an internal pressure of approximately 1 MPa to 10 MPa to the inside of the extruder to fill the inside of a biaxial extruder with the resin raw material. As a result, the kneading can be performed more efficiently with low shear, so that uniform dispersion is promoted while suppressing thermal decomposition. An adjustment of the kneading resin pressure can be performed by adjusting Q/N (discharge amount per one rotation of screw) or by providing a pressure adjusting valve at the outlet of the biaxial kneading extruder.

(10) Shear and Screw Type

In order to uniformly disperse the plurality of types of raw materials, it is preferable to impart shear to the raw materials. However, the molecular chain breakage or gel generation may occur due to excessive shearing of the raw materials. Therefore, it is preferable to appropriately select a rotor segment, the number of kneading discs, or a clearance to be disposed on the screw. In general, since the rotor segment has large clearance, the rotor segment tends to have lower shear than the kneading disc type.

A shear rate (shear rate during the pelletization) is preferably 60 sec⁻¹ to 1000 sec⁻¹, more preferably 100 sec⁻¹ to 800 sec⁻¹, and particularly preferably 200 sec⁻¹ to 500 sec⁻¹. In a case where the shear rate is set to the lower limit value or more, it is possible to suppress occurrence of melting defects of raw materials and occurrence of dispersion defects of additives. In a case where the shear rate is set to the upper limit value or less, a breakage of a molecular chain can be suppressed, and it is possible to suppress a decrease in molecular weight and an increase in generation of crosslinked gel.

(11) Retention Time

A retention time of the extruder can be calculated from a volume of a resin retention portion in the extruder and a discharge capacity of the raw materials. An extrusion retention time of the raw materials in the pelletization is preferably 10 seconds to 30 minutes, more preferably 15 seconds to 10 minutes, and particularly preferably 30 seconds to 3 minutes. Deterioration of the resin and discoloration of the resin can be suppressed as long as sufficient melting can be ensured, so that it is preferable that the retention time is short.

(12) Pelletizing Method

Pelletizing means forming a resin into a pellet shape.

As a pelletizing method, a method in which the resin is extruded into noodles, solidified in water, and then cut is generally used, but the pelletization may be performed by an under water cut method for cutting while directly extruding from a mouthpiece into water after melting the resin with the extruder, or a hot cut method for cutting the resin while still hot.

(13) Pellet Size

A pellet size is preferably 1 mm² to 300 mm² in a cross-sectional area and 1 mm to 30 mm in a length, and particularly preferably 2 mm² to 100 mm² in a cross-sectional area and 1.5 mm to 10 mm in a length.

(14) Other Pelletization

As the pelletization, the above-described melt-kneading method using an extruder is generally used, but a method of producing a uniformly dispersed solution of the liquid crystal polymer and the additives with a common solvent, and removing the solvent to solidify the liquid crystal polymer and the additives can also be used.

Examples of the solvent include methyl alcohol, ethyl alcohol, acetone, methyl ethyl ketone, diethyl ether, ethyl acetate, butyl acetate, and dichloromethane.

From the viewpoint of efficiency and dispersibility, a concentration the raw materials in the uniformly dispersed solution is preferably 1% by mass to 50% by mass, more preferably 3% by mass to 35% by mass, and particularly preferably 5% by mass to 30% by mass with respect to the entire uniformly dispersed solution.

The solidification may be performed by drying the solvent after the dissolution (drying method), or may be performed by putting a poor solvent into the solution after the dissolution to be precipitated (precipitation method).

(Drying)

(1) Purpose of Drying

Before a molten film formation, it is preferable to reduce a moisture and a volatile fraction in the pellets, and it is effective to dry the pellets. In a case where the pellets include a moisture and a volatile fraction, it may cause deterioration of appearance due to inclusion of bubbles in the formed film or reduction of haze. Furthermore, there may be a case where physical properties are deteriorated due to the molecular chain breakage of the liquid crystal polymer, or roll contamination is generated due to generation of monomer or oligomer. In addition, depending on the type of the liquid crystal polymer used, it may be possible to suppress generation of an oxidative crosslinked substance during molten film formation by removing dissolved oxygen by the drying.

(2) Drying Method and Heating Method

As a drying method, from the viewpoint of drying efficiency or economical efficiency, a dehumidifying hot air dryer is generally used, but the drying method is not particularly limited as long as a desired moisture content can be obtained. In addition, as the drying method, a more appropriate method is selected according to characteristics of the physical properties of the liquid crystal polymer.

Examples of a heating method include pressurized steam, heater heating, far-infrared irradiation, microwave heating, and a heat medium circulation heating method.

From the viewpoint of using energy more effectively and viewpoint of uniform drying by reducing temperature unevenness, it is preferable to provide a heat insulating structure in a drying equipment.

The pellets can also be stirred to increase the drying efficiency. The drying method is not limited to one type, and a plurality of types can be combined.

(3) Form of Device

There are two types of drying method, a continuous method and a batch method. In the drying method using a vacuum, a batch method is preferable. On the other hand, in the drying method in a steady state, a continuous method is preferable.

(4) Atmosphere and Air Volume

In a case where the pellets are dried, it is preferable to blow a gas.

Examples of the gas to be blown in the case of drying the pellets include air and an inert gas.

A dew point of the air or the inert gas is preferably 0° C. to −60° C., more preferably −10° C. to −55° C., and particularly preferably −20° C. to −50° C. Setting a low dew point is preferable from the viewpoint of reducing the volatile matter content contained in the pellets, but is disadvantageous from the viewpoint of economical efficiency, and an appropriate range may be selected.

In a case where the raw material is easily oxidized, it is also effective to use an inert gas to reduce oxygen partial pressure.

In drying the pellets, an air volume required per ton of the liquid crystal polymer is preferably 20 m³/hour to 2000 m³/hour, more preferably 50 m³/hour to 1000 m³/hour, and particularly preferably 100 m³/hour to 500 m³/hour. In a case where the drying air volume is equal to or more than the lower limit value, the drying efficiency is improved. In a case where the drying air volume is equal to or less than the upper limit value, it is economically preferred.

The pellets may be dried under reduced pressure.

(5) Temperature and Time

In a case where the raw material is in an amorphous state, a drying temperature is preferably {Glass transition temperature (Tg) (° C.)−1° C.} to {Tg (° C.)−100° C.} (that is, a temperature 1° C. to 100° C. lower than Tg), more preferably {Tg (° C.)−5° C.} to {Tg (° C.)−60° C.}, and particularly preferably {Tg (° C.)−10} to {Tg (° C.)−40° C.}.

In a case where the drying temperature is equal to or less than the upper limit value, since blocking (phenomenon in which the pellets adhere to each other and become difficult to peel off easily) due to softening of the resin can be suppressed, transportability is excellent. On the other hand, in a case where the drying temperature is equal to or more than the lower limit value, the drying efficiency can be improved, and the moisture content can be set to a desired value.

In addition, in a case where the raw material is a crystalline resin, the resin can be dried without melting in a case of {Melting point (Tm) (° C.)−30° C.} or lower. In a case where the drying temperature is too high, coloration or a change in molecular weight (generally decreased, but in some cases, increased) may occur. In addition, since the drying efficiency is low even in a case where the drying temperature is too low, it is necessary to select appropriate conditions. As a guide, {Tm (° C.)−150° C.} to {Tm (° C.)−50° C.} is preferable.

A drying time is preferably 15 minutes or more, more preferably 1 hour or more, and particularly preferably 2 hours or more. Even in a case of being dried for more than 50 hours, an effect of further reducing the water content is small and there is a concern about thermal deterioration of the resin, so that it is not necessary to lengthen the drying time unnecessarily.

(6) Moisture Content

A moisture content of the pellets is preferably 1.0% by mass or less, more preferably 0.1% by mass or less, and particularly preferably 0.01% by mass or less with respect to the entire pellets.

(7) Transportation Method

In order to prevent water re-adsorption to the dried pellets, it is preferable that the pellets are transported under a dry air or dry nitrogen atmosphere. In addition, it is common to use heated dry air for stabilizing the extrusion.

[Film Forming Step]

The film forming step is not particularly limited, but is preferably a step of extruding the melt-kneaded liquid crystal polymer (that is, the pellets) with a die to form a film.

Hereinafter, a manufacturing device used in the film forming step and a film-forming procedure of the film will be described.

(Manufacturing Device)

Hereinafter, an example of each equipment constituting the manufacturing device will be described.

(Extruder, Screw, and Barrel (hereinafter, the barrel is also referred to as a “cylinder”))

(1) Extruder

A known melt extruder can be used as the extruder. Examples of the extruder include screw type monoaxial extruders such as full-flight, Maddock, and Dulmage, and co-rotaining or anti-rotating type biaxial extruders.

(2) Type of Extruder

Examples of the extruder include a monoaxial extruder and a biaxial (or multiaxial) extruder.

The biaxial (or multiaxial) extruder is roughly classified into an meshing type and a non-meshing type, but is not particularly limited thereto. In addition, a screw rotation direction of the biaxial (or multiaxial) extruder is divided into the same direction and different directions, but is not particularly limited thereto.

(3) Screw Type and Structure

Here, an example of a screw for a monoaxial extruder is shown. Examples of the screw include a full-flight screw and a double-flight screw. In addition, in order to improve kneading property in the extruder, the screw may have a mixing element such as Maddock, Dulmage, and a barrier.

Diameter and Groove Depth

A screw diameter varies depending on the target extrusion amount per unit time, but is preferably 10 mm to 300 mm, more preferably 20 mm to 250 mm, and particularly preferably 30 mm to 150 mm. A groove depth in a supply unit of the screw is preferably 0.05 times to 0.20 times, more preferably 0.07 times to 0.18 times, and particularly preferably 0.08 times to 0.17 times the screw diameter. A flight pitch is not particularly limited, but is preferably set to the same value as the screw diameter. In addition, a flight groove width is preferably 0.05 times to 0.25 times the screw flight pitch. A clearance between the flight and the barrel is preferably also 0.001 times to 0.005 times the screw diameter, and from the viewpoint of friction between the barrels and reduction of the retention portion, more preferably 0.0015 times to 0.004 times.

Compression Rate

A screw compression ratio of the extruder is preferably 1.6 to 4.5. Here, the screw compression ratio is represented by a volume ratio between the supply unit and a measuring unit, that is, (Volume per unit length of supply unit)÷(Volume per unit length of measuring unit). The screw compression ratio is calculated using an outer diameter of a screw shaft of the supply unit, an outer diameter of a screw shaft of the measuring unit, a groove part diameter of the supply unit, and a groove part diameter of the measuring unit. In a case where the screw compression ratio is 1.6 or more, sufficient melt-kneading properties are obtained, and generation of undissolved portions can be suppressed. In a case where the screw compression ratio is 4.5 or less, it is possible to prevent excessive shear stress from being applied. Specifically, it is possible to suppress a decrease in the mechanical strength of the film due to molecular chain breakage, a superheat coloring phenomenon due to shear heat generation, and a decrease in foreign matter level due to gel generation. Therefore, the appropriate screw compression ratio is preferably 1.6 to 4.5, more preferably 1.7 to 4.2, and particularly preferably 1.8 to 4.0.

L/D

L/D is a ratio of the cylinder length to the cylinder inner diameter. In a case where the L/D is 20 or more, melting and kneading are sufficient, and the generation of undissolved foreign matter in the film after manufacturing can be suppressed as in the case where the compression ratio is appropriate. In addition, in a case where the L/D is 70 or less, the retention time of the liquid crystal polymer in the extruder is shortened, so that the deterioration of the resin can be suppressed. Moreover, in a case where the L/D is 70 or less, the decrease in the mechanical strength of the film caused by the decrease in the molecular weight due to the breakage of the molecular chain can be suppressed. Therefore, the L/D is preferably in a range of 20 to 70, more preferably in a range of 22 to 65, and particularly preferably in a range of 24 to 50.

Screw Proportion

A length of the extruder supply unit is preferably 20% to 60%, more preferably 30% to 50% with respect to an effective screw length (total length of the supply unit, compression unit, and measuring unit). A length of the extruder compression unit is preferably 5% to 50% with respect to the effective screw length, is preferably 5% to 40% in a case of a crystalline resin and preferably 10% to 50% in a case of an amorphous resin. The measuring unit preferably has a 20% to 60% length of the effective screw length, and more preferably 30% to 50% length. It is also common practice to divide the measuring unit into a plurality of parts and arrange a mixing element between them to improve the kneading property.

Q/N

A discharge amount per one rotation of the screw (Q/N) is preferably 50% to 99%, more preferably 60% to 95%, and particularly preferably 70% to 90% of a theoretical maximum discharge amount (Q/N)_{MAX}. Q represents a discharge amount [cm³/min], and N represents a screw rotation speed [rpm]. In a case where the discharge amount per one rotation of the screw (Q/N) is 50% or more of the theoretical maximum discharge amount (Q/N)_{MAX}, the retention time in the extruder can be shortened and the progress of thermal deterioration inside the extruder can be suppressed. In addition, in a case where the discharge amount per one rotation of the screw (Q/N) is 99% or less of the theoretical maximum discharge amount (Q/N)_{MAX}, since back pressure is sufficient, the kneading property is improved, and not only the melting uniformity is improved, but also the stability of the extrusion pressure is improved.

(4) Extrusion Conditions

Drying

In the melt plasticization step for pellets using an extruder, it is preferable to reduce a moisture and a volatile fraction in the pellets as in the pelletizing step, and it is effective to dry the pellets.

Method for Supplying Raw Materials

In a case where there are multiple types of raw materials (pellets) input from the extruder supply port, the raw materials may be mixed in advance (premix method), may be separately supplied into the extruder in a fixed proportion, or may be a combination of both. In addition, in order to stabilize the extrusion, it may be also possible to control the temperature of the raw materials charged from the supply port, thereby controlling fluctuations in bulk specific gravity. In addition, from the viewpoint of plasticization efficiency, the raw material temperature is preferably a high temperature as long as the raw material temperature is within a range in which the raw materials does not block the supply port by pressure-sensitively adhering to the supply port. In a case of an amorphous state, the raw material temperature is preferably in a range of {Glass transition temperature (Tg) (° C.)−150° C.} to {Tg (° C.)−1° C.}, and in a case of a crystalline resin, the raw material temperature is preferably in a range of {Melting point (Tm) (° C.)−150° C.} to {Tm (° C.)−1° C.}. In addition, from the viewpoint of thermoplastic efficiency, the bulk specific gravity of the raw material is preferably 0.3 times or more, and particularly preferably 0.4 times or more in a case of a molten state. In a case where the bulk specific gravity of the raw material is less than 0.3 times the specific density in the molten state, a processing treatment such as compression of the raw materials to form pseudo-pellets is performed.

Atmosphere During Extrusion

As for the atmosphere during melt extrusion, it is effective to inject an inert gas (nitrogen or the like) within a range in which the inert gas does not interfere with uniform dispersion, as in the pelletizing step. It is also effective to reduce the oxygen concentration in the extruder by using a vacuum hopper or provide a vent port in the extruder to reduce the pressure by a vacuum pump. These depressurization or injection of the inert gas may be carried out independently or in combination.

Rotation Speed

A screw rotation speed of the extruder is preferably 5 rpm to 300 rpm, more preferably 10 rpm to 200 rpm, and particularly more preferably 15 rpm to 100 rpm. In a case where the screw rotation speed is set to equal to or more than the lower limit value, since a retention time of the resin in the extruder is shortened, it is possible to suppress the decrease in molecular weight due to thermal deterioration of the resin and to suppress discoloration of the resin. In a case where the rotation speed is set to equal to or less than the upper limit value, a breakage of a molecular chain due to shearing can be suppressed, and the decrease in the molecular weight or the increase in generation of crosslinked gel can be suppressed. It is preferable to select appropriate conditions for the screw rotation speed from the viewpoint of uniform dispersibility and suppression of thermal deterioration due to extension of the retention time.

Temperature

A barrel temperature (supply unit temperature T₁° C., compression unit temperature T₂° C., and measuring unit temperature T₃° C.) is generally determined by the following method. In a case where the pellets are melt-plasticized at a target temperature T° C. by the extruder, the measuring unit temperature T₃ is set to T±20° C. in consideration of the shear calorific value. In this case, T₂ is set within a range of T₃±20° C. in consideration of extrusion stability and thermal decomposability of the resin. Generally, T₁ is set to {T₂ (° C.)−5° C.} to {T₂ (° C.)−150° C.}, and the optimum value of T₁ is selected in terms of ensuring a friction between the resin and the barrel, which is a driving force (feed force) for feeding the resin, and preheating at a feed unit. In a case of a normal extruder, it is possible to subdivide each region of T₁ to T₃ and set the temperature, and by performing settings such that the temperature change between each region is gentle, it is possible to make it more stable. In this case, T is preferably set to be equal to or lower than the thermal deterioration temperature of the resin, and in a case where the thermal deterioration temperature is exceeded due to the shear heat generation of the extruder, it is generally performed to positively cool and remove the shear heat generation. In addition, in order to achieve both improvement in dispersibility and thermal deterioration, it is also effective to melt and mix a first half part in the extruder at a relatively high temperature and lower the resin temperature in a second half part.

Screw Temperature Control

Controlling the temperature of the screw is also performed to stabilize the extrusion. Examples of a method for controlling the temperature include a method of flowing a medium such as water inside the screw and a method of heating by incorporating a heater inside the screw.

Pressure

A resin pressure in the extruder is generally 1 MPa to 50 MPa, and in terms of extrusion stability and melt uniformity, it is preferably 2 MPa to 30 MPa and particularly preferably 3 MPa to 20 MPa. In a case where the resin pressure in the extruder is 1 MPa or more, a filling rate of the melting in the extruder (resin in a molten state) is sufficient, so that the destabilization of the extrusion pressure and the generation of foreign matter due to the generation of retention portions can be suppressed. In addition, in a case where the resin pressure in the extruder is 50 MPa or less, it is possible to suppress the excessive shear stress received in the extruder, so that thermal decomposition due to an increase in the resin temperature can be suppressed.

Retention Time

A retention time in the extruder (retention time during film formation) can be calculated from a volume of the extruder portion and a discharge capacity of the polymer, as in the pelletizing step. The retention time is preferably 10 seconds to 30 minutes, more preferably 15 seconds to 15 minutes, and particularly preferably 30 seconds to 10 minutes. In a case where the retention time is 10 seconds or more, the melt plasticization and the dispersion of the additives are improved.

In a case where the retention time is 30 minutes or less, it is preferable from the viewpoint that resin deterioration and discoloration of the resin can be suppressed.

(Filtration (Screen Changer))

Type, Purpose of Installation, and Structure

It is generally used to provide a filtration equipment at the outlet of the extruder in order to prevent damage to the gear pump due to foreign matter included in the raw material and to extend the life of the filter having a fine pore size installed downstream of the extruder. It is preferable to perform so-called breaker plate type filtration in which a mesh-shaped filtering medium is used in combination with a reinforcing plate having a high opening ratio and having strength.

Mesh Size and Filtration Area

A mesh size is preferably 40 mesh to 800 mesh, more preferably 60 mesh to 700 mesh, and still more preferably 100 mesh to 600 mesh. In a case where the mesh size is 40 mesh or more, it is possible to sufficiently suppress foreign matter from passing through the mesh. In addition, in a case where the mesh is 800 mesh or less, the improvement of the filtration pressure increase speed can be suppressed and the mesh replacement frequency can be reduced. A filtration area is preferably selected with a flow rate of 0.05 g/cm² to 5 g/cm² per second as a guide, more preferably 0.1 g/cm² to 3 g/cm², and particularly preferably 0.2 g/cm² to 2 g/cm².

(Microfiltration)

Type, Purpose of Installation, and Structure

In order to perform foreign matter filtration with higher accuracy, it is preferable to provide a precision filter device with high filtration accuracy before extrusion from the die. It is preferable that a filtration accuracy of the filtering medium of the filter is high, but from the viewpoint of the pressure resistance of the filtering medium and the suppression of the increase in the filter pressure due to clogging of the filtering medium, the filtration accuracy is preferably 3 μm to 30 μm, more preferably 3 μm to 20 μm, and particularly preferably 3 μm to 10 μm. The microfiltration device is usually provided at one place, but multi-stage filtration performed at a plurality of places in series or in parallel may be performed. From the viewpoint that a large filtration area can be obtained and pressure resistance is high, it is preferable to provide a filtration device incorporating a leaf type disc filter.

The filtration area varies depending on the melt viscosity of the resin to be filtered, but is preferably 5 g·cm⁻²·h⁻¹ to 100 g·cm⁻²·h⁻¹, more preferably 10 g·cm⁻²·h⁻¹ to 75 g·cm⁻²·h⁻¹, and particularly preferably 15 g·cm⁻²·h⁻¹ to 50 g·cm⁻²·h⁻¹.

As a type of the filtering medium, it is preferable to use a steel material from the viewpoint of being used under high temperature and high pressure, and it is more preferable to use stainless steel or steel among the steel materials, and it is particularly preferable to use stainless steel from the viewpoint of corrosion.

A thickness of the filtering medium is preferably 200 μm to 3 mm, more preferably 300 μm to 2 mm, and particularly preferably 400 μm to 1.5 mm.

A porosity of the filtering medium is preferably 50% or more and particularly preferably 70% or more. In a case of being 50% or more, the pressure loss is low and the clogging is small, so that the operation can be performed for a long time. The porosity of the filtering medium is preferably 90% or less. In a case of being 90% or less, it is possible to suppress the filtering medium from being crushed in a case where the filter pressure rises, so that the rise in the filter pressure can be suppressed.

(Connection Pipe and the Like)

Pipes (adapter pipe, switching valve, and mixing device) connecting each unit of the film-forming device are also required to be excellent in corrosion resistance and heat resistance as well as the barrel and screw of the extruder. As a material of the pipe, chrome molybdenum steel, nickel chrome molybdenum steel, or stainless steel is used. In addition, in order to improve the corrosion resistance, it is preferable that a surface of a polymer flow channel (surface inside the pipe) is plated with HCr, Ni, or the like.

In addition, in order to prevent retention inside the pipe, a surface roughness inside the pipe is preferably Ra=200 nm or less, and more preferably Ra=150 nm or less.

A pipe diameter is preferably 5 Kg·cm⁻²·h⁻¹ to 200 Kg·cm⁻²·h⁻¹, more preferably 10 Kg·cm⁻²·h⁻¹ to 150 Kg·cm⁻²·h⁻¹, and particularly preferably 15 Kg·cm⁻²·h⁻¹ to 100 Kg·cm⁻²·h⁻¹.

In order to stabilize the extrusion pressure of the liquid crystal polymer having a high temperature dependence of the melt viscosity, it is preferable to minimize the temperature fluctuation of the piping portion as well. Generally, a band heater having a low equipment cost is often used for heating the pipe, but an aluminum cast heater having a small temperature fluctuation or a method using a heat medium circulation is more preferable. In addition, it is preferable to divide the pipe into a plurality of pipes as in the case of the cylinder barrel and control each region individually from the viewpoint of reducing temperature unevenness. Moreover, as for the temperature control, Proportional-Integral-Differential (PID) controller is generally used, but it is more preferable to use in combination with a method of variably controlling the heater output using an AC power regulator.

In addition, installing a mixing device in the flow channel of the extruder is also effective for uniformizing the film. As the mixing device, it is effective to use a spiral type or stator type static mixer. By using an n-stage static mixer, homogenization is divided into 2n, so that as n is larger, uniformization is further promoted. For uniformizing the film, 5 stages to 20 stages are preferable, and 7 stages to 15 stages are more preferable. It is preferable to extrude from the die immediately after the uniformization with a static mixer to form a film.

(Gear Pump)

In order to improve thickness accuracy of the film, it is preferable to reduce the fluctuation of the discharge amount. It is preferable to provide a gear pump between the extruder and the die.

Type and Size

As the gear pump, it is preferable to use a normal two-gear type in which quantification is performed by a meshing rotation of two gears or a three-gear type in which quantification is performed by a meshing rotation of three gears. A size of the gear pump is generally selected to have a capacity such that the rotation speed is 5 rpm to 50 rpm under the extrusion conditions, preferably 7 rpm to 45 rpm, and particularly preferably 8 rpm to 40 rpm.

By selecting the size of the gear pump in which the rotation speed is within the above-described range, it is possible to suppress the resin temperature rise due to shear heat generation and suppress the resin deterioration due to the retention inside the gear pump.

In addition, since the gear pump is constantly worn by the meshing of gears, it is required to use a material having excellent abrasion resistance, and it is preferable to use an abrasion-resistant material same as the screw or the barrel.

Countermeasures for Retention Portion

It is required for the gear pump to be designed (particularly, with respect to clearance) in accordance with the melt viscosity of the liquid crystal polymer. In addition, in some cases, the retention portion of the gear pump causes deterioration of the liquid crystal polymer, so a structure with as little stagnant as possible is preferable.

Operating Conditions

In a case where a difference between a primary pressure (input pressure) and a secondary pressure (output pressure) is too large in the gear pump, the load on the gear pump is large and the shear heat generation is large. Therefore, a differential pressure (difference between the primary pressure (input pressure) and the secondary pressure (output pressure)) during operation is preferably within 20 MPa, more preferably within 15 MPa, and particularly preferably within 10 MPa. In addition, it is also effective to control the screw rotation of the extruder or use a pressure control valve to keep the primary pressure of the gear pump constant in order to make the film thickness uniform.

(Die)

Type, Structure, and Material

The molten resin from which foreign matters have been removed by filtration and in which the temperature has been made uniform by a mixer is continuously sent to the die. Any type of commonly used T-die, fishtail die, or hanger coat die can be used as long as the die is designed so that the retention of molten resin is small. Among those, from the viewpoint of easily obtaining a liquid crystal polymer film having high tear resistance and excellent film-forming properties, a T-die is preferable.

A clearance of a T-die outlet portion (lip clearance) is preferably 1 times to 20 times, more preferably 1.5 times to 15 times, and particularly preferably 2.0 times to 10 times the film thickness.

In a case where the lip clearance is 1 times or more of the film thickness, an increase in the internal pressure of the die can be suppressed, so that the film thickness can be easily controlled, and a sheet having a good surface shape can be obtained by film formation. In addition, in a case where the lip clearance is 20 times or less of the film thickness, it is possible to prevent the draft ratio from becoming too large, so that the sheet thickness accuracy is good.

The thickness of the film is generally adjusted by adjusting the clearance of the mouthpiece at the tip part of the die, and it is preferable to use a flexible lip from the viewpoint of thickness accuracy, but in some cases, a choke bar may be used for adjustment.

The clearance adjustment of the mouthpiece can be changed by using the adjustment bolt at the die outlet portion. The adjustment bolts are preferably arranged at intervals of 15 mm to 50 mm, more preferably at intervals of 35 mm or less, and still more preferably at intervals of 25 mm or less. In a case where the interval is 50 mm or less, the occurrence of thickness unevenness between the adjustment bolts can be suppressed. In a case where the interval is 15 mm or more, stiffness of the adjustment bolt is sufficient, so that the fluctuation of the internal pressure of the die can be suppressed and the fluctuation of the film thickness can be suppressed. In addition, an inner wall surface of the die is preferably smooth from the viewpoint of wall retention, and for example, the surface smoothness can be improved by polishing. In some cases, after the inner wall surface is plated, the smoothness is increased by polishing, or peelability from the polymer is improved by vapor deposition.

In addition, it is preferable that the flow rate of the polymer discharged from the die is uniform in the width direction of the die. Therefore, it is preferable to change the manifold shape of the die to be used depending on the melt viscosity shear rate dependence of the liquid crystal polymer to be used.

In addition, it is preferable that the temperature of the polymer discharged from the die is also uniform in the width direction of the die. Therefore, it is preferable to make the temperature uniform by raising the set temperature of the die end part having a large heat dissipation of the die or by taking measures such as suppressing the heat dissipation of the die end part.

In addition, since insufficient processing precision of the die or foreign matters adhering to the die outlet portion causes die streak, which causes a significant deterioration in quality of the film, it is preferable that the die lip portion is smooth. An arithmetic average surface roughness Ra of the die lip portion is preferably 0.05 μm or less, more preferably 0.03 m or less, and particularly preferably 0.02 μm or less. In addition, a curvature radius R of the die lip edge portion is preferably 100 μm or less, more preferably 70 μm or less, and particularly preferably 50 μm or less. In addition, by spraying ceramic, one processed into a sharp edge with a curvature radius R=20 μm or less can also be used.

To reduce the thickness variation in long-term continuous production, an automatic thickness adjustment die that measures the film thickness downstream, calculates the thickness deviation, and feeds back the result to the thickness adjustment of the die is also effective.

The area between the die and the roll landing point of the polymer is called an air gap, and it is preferable that the air gap is short in order to improve the thickness accuracy and stabilize the film formation by reducing the neck-in amount (increasing the edge thickness by reducing the film width). By making the angle of the tip of the die tip part acute or reducing the thickness of the die, it is possible to prevent interference between the roll and the die, and shorten the air gap. On the other hand, by making the angle of the tip of the die tip part acute or reducing the thickness of the die, stiffness of the die may be lowered, and the pressure of the resin may cause the center portion of the die to open, resulting in a decrease in thickness accuracy. Therefore, it is preferable to select conditions which can achieve both the stiffness of the die and the shortening of the air gap.

Multi-Layer Film Formation

A single-layer film forming apparatus having a low equipment cost is generally used for manufacturing a film. However, in a case where a functional layer is provided on the outer layer of the liquid crystal polymer film, a multi-layer film forming apparatus capable of manufacturing a film having two or more kinds of structures may be used. Specific examples of a manufacturing method of the film using a multi-layer film forming apparatus include a method of performing multi-layering using a multi-layer feed block and a method of using a multi-manifold die. Generally, it is preferable to laminate the functional layer thinly on the surface layer, but the layer ratio is not particularly limited.

A retention time (retention time from passing through the extruder to discharging the die) from the pellets entering the extruder through the supply port and exiting from the supply unit (for example, die) is preferably 1 minutes to 30 minutes, more preferably 2 minutes to 20 minutes, and particularly preferably 3 minutes to 10 minutes. From the viewpoint of thermal deterioration of the polymer, it is preferable to select equipment having a short retention time. However, in order to reduce the volume inside the extruder, for example, in a case where the capacity of the filtration filter is too small, the filter life may be shortened and the replacement frequency may increase. In addition, making the pipe diameter too small may also increase the pressure loss. For this reason, it is preferable to select equipment of appropriate size.

In addition, by setting the retention time to 30 minutes or less, it is easy to adjust the diameter corresponding to the maximum equivalent circle diameter of the bright portion to the above-described range.

(Cast)

The film forming step preferably includes a step of supplying the molten liquid crystal polymer from the supply unit and a step of landing the molten liquid crystal polymer on a cast roll to form a film. The molten liquid crystal polymer may be cooled and solidified and wound as it is as a film, or it may be passed between a pair of compression surfaces and continuously pressed to form a film.

In this case, there is no particular limitation on the unit for supplying the liquid crystal polymer (melting) in a molten state. For example, as a specific unit for supplying the melting, an extruder which melts the liquid crystal polymer and extrudes it into a film may be used, an extruder and a die may be used, or the liquid crystal polymer may be once solidified into a film and then melted by a heating unit to form a melt, which may be supplied to the film forming step.

In a case where the molten resin extruded from the die into a sheet is pressed by a device having a pair of compression surfaces, not only can the surface morphology of the compression surface be transferred to the film, but aligning properties can be controlled by imparting elongation deformation to the composition containing the liquid crystal polymer.

Film Forming Method and Type

Among the methods for forming a molten liquid crystal polymer into a film, it is preferable to pass between two rolls (for example, a touch roll and a chill roll) from the viewpoint that a high pinching pressure can be applied and the film surface is excellent. In the present specification, in a case where a plurality of cast rolls for transporting the melt are provided, the cast roll closest to the most upstream liquid crystal polymer supply unit (for example, die) is referred to as a chill roll. In addition, a method of pressing metal belts with each other or a method of combining a roll and a metal belt can also be used. In some cases, in order to improve adhesiveness with rolls or metal belts, a film forming method such as a static electricity application method, an air knife method, an air chamber method, and a vacuum nozzle method can be used in combination on a cast drum.

Roll Type and Material

As the cast roll, from the viewpoint of surface roughness, uniformity of pressing in a case of pinching, and uniformity of roll temperature, a metal roll is preferable.

Carbon steel and stainless steel are generally used as the material for the rigid metal roll, and chromium molybdenum steel, nickel chrome molybdenum steel, or cast iron can be used. Further, in order to modify the surface properties such as film peelability, plating treatment such as chromium or nickel, or processing such as ceramic spraying may be performed. In a case where a metal belt is used, the thickness of the belt is preferably 0.5 mm or more, more preferably 1 mm or more, and particularly preferably 2 mm or more in order to apply the necessary pinching pressure.

The roll nip length suitable for applying the pinching pressure by the pair of rolls is preferably more than 0 mm and within 5 m, and more preferably more than 0 mm and within 3 mm.

Roll Diameter

As the cast roll, it is preferable to use a roll having a large diameter, and specifically, the diameter is preferably 200 mm to 1500 mm. It is preferable to use a roll having a large diameter because the deflection of the roll can be reduced and a high pinching pressure can be uniformly applied in a case of pressing. In addition, in the manufacturing method according to the embodiment of the present disclosure, the diameters of the two rolls to be pressed may be the same or different from each other.

Roll Hardness

In order to apply the pressure between rolls in the above-described range, a shore hardness of the roll is preferably 45 HS or more, more preferably 50 HS or more, and particularly preferably 60 HS to 90 HS. The shore hardness can be obtained from the average value of the values measured at 5 points in the roll width direction and 5 points in the circumferential direction using the method of JIS Z 2246.

Surface Roughness, Cylindricity, Roundness, and Diameter Runout

A surface of the cast roll and the touch roll preferably has an arithmetic average surface roughness Ra of 100 nm or less, more preferably 50 nm or less, and particularly preferably 25 nm or less.

The roundness is preferably 5 μm or less, more preferably 3 μm or less, and particularly preferably 2 μm or less. The cylindricity is preferably 5 μm or less, more preferably 3 μm or less, and particularly preferably 2 μm or less. The diameter runout is preferably 7 μm or less, more preferably 4 μm, and particularly preferably 3 μm or less. The cylindricity, roundness, and diameter runout can be obtained by the method of JIS B 0621.

Roll Surface Properties

As the cast roll and the touch roll, the surface is preferably a mirror surface, and generally, a roll having a hard chrome-plated surface mirror-finished is used.

From the viewpoint of film smoothness after film formation, it is preferable that the roll surface is smooth. On the other hand, from the viewpoint of imparting sliding properties of the film, it is also possible to use a mirror pocket surface roll for forming unevenness on the film surface. Alternatively, it is possible to use a blasted roll or a dimpled roll for forming fine unevenness on the film surface. However, from the viewpoint of film smoothness, the unevenness of the roll is preferably Ra=10 μm or less. In addition, it is also possible to use a roll in which 50 to 1000 fine grooves or prism shapes having a depth of 0.1 to 10 μm are engraved on the surface of the roll per 1 mm².

Roll Temperature

It is preferable that the roll can quickly remove the heat supplied from the molten polymer and maintain a constant roll surface temperature. Therefore, it is preferable to pass a medium having a constant temperature inside the roll. As the medium, water, a thermal medium oil, or a gas is preferably used. In addition, a known method can be used as a method for making the roll surface temperature constant.

Molten Polymer Temperature

From the viewpoint of improving the moldability of the liquid crystal polymer and suppressing deterioration, the discharge temperature (resin temperature at the outlet of the supply unit) is preferably (Tm of liquid crystal polymer−10)° C. to (Tm of liquid crystal polymer+40)° C. A standard for the melt viscosity is preferably 50 Pa·s to 3,500 Pa·s.

It is preferable that the cooling of the molten polymer between the air gaps is as small as possible, and it is preferable to reduce the temperature drop due to cooling by taking measures such as increasing the film forming speed and shortening the air gap.

Touch Roll Temperature

A temperature of the touch roll is preferably set to Tg or less of the liquid crystal polymer. In a case where the temperature of the touch roll is Tg or less of the liquid crystal polymer, the molten polymer can be suppressed from pressure-sensitively adhering to the roll, so that the film appearance is improved. For the same reason, the chill roll temperature is preferably set to Tg or less of the liquid crystal polymer.

Film Formation Speed and Circumferential Speed Difference

From the viewpoint of heat retention of the melting in the air gap, a film forming speed is preferably 3 m/min or more, more preferably 5 m/min or more, and particularly preferably 7 m/min or more. In a case where the film forming speed is increased, cooling of the melt in the air gap can be suppressed, and more uniform pinching pressure and shear deformation can be imparted in a case where the temperature of the melting is high. The above-described film forming speed is defined as the slow second compression surface speed in a case where the molten polymer passes between the two rolls to be pinched.

It is preferable that the moving speed of the first compression surface is faster than the moving speed of the second compression surface. Furthermore, it is preferable that the film according to the embodiment of the present disclosure is manufactured by adjusting a moving speed ratio between the first compression surface and the second compression surface of the pinching device to 0.60 to 0.99, and applying shear stress in a case where the molten resin passes through the pinching device. The two compression surfaces may be driven around or independently, but are preferably driven independently from the viewpoint of uniformity of film properties.

(Procedure for Forming Film)

Film Formation Procedure

In the film forming step, it is preferable to perform the film formation by the following procedure from the viewpoint of stabilization of quality.

The molten polymer discharged from the die is landed on a cast roll to form a film, which is then cooled and solidified and wound up as a film.

In a case of pressing the molten polymer, the molten polymer is passed between the first compression surface and the second compression surface set at a predetermined temperature, and then is cooled and solidified and wound up as a film.

Transport Tension

A transport tension of the film can be appropriately adjusted depending on the film thickness, and the transport tension per 1 m width of the film is preferably 10 N/m to 500 N/m, more preferably 20 N/m to 300 N/m, and particularly preferably 30 N/m to 200 N/m. Generally, as the film is thicker, it is necessary to increase the transport tension. For example, in the case of a film having a thickness of 100 μm, 30 to 150 N/m is preferable, 40 to 120 N/m is more preferable, and 50 to 100 N/m is particularly preferable. In a case where the transport tension of the film is at least the lower limit value, meandering of the film during film transport can be suppressed, so that slippage between the guide roll and the film can be suppressed and scratches on the film can be suppressed. In a case where the transport tension of the film is the upper limit value or less, it is possible to suppress vertical wrinkles in the film, and it is possible to prevent the film from being forcibly stretched and broken.

For the tension control of the film, any method such as a dancer method, a torque control method using a servo motor, a powder clutch/brake method, and a friction roll control method may be used, but from the viewpoint of control accuracy, a dancer method is preferable. It is not necessary to make all the transport tensions the same value in the film forming step, and it is also useful to adjust the transport tension to an appropriate value for each region where the tension is cut.

It is preferable that the transport roll has no roll deflection deformation due to transport tension, small mechanical loss, sufficient friction with the film, and a smooth surface so as not to be scratched during film transport. In a case where a transport roll having a small mechanical loss is used, a large tension is not required for transporting the film, and it is possible to suppress scratches on the film. In addition, it is preferable that the transport roll has a large holding angle of the film in order to remove friction with the film. The holding angle is preferably 900 or more, more preferably 1000 or more, and particularly preferably 120° or more. In a case where a sufficient holding angle cannot be obtained, it is preferable to use a rubber roll or a roll having a satin finish, a dimple shape, or a groove on the surface of the roll to secure friction.

Take-Up Tension

It is preferable to appropriately adjust a take-up tension according to the film thickness as well as the film transport tension. The take-up tension per 1 m width of the film is preferably 10 N/m to 500 N/m, more preferably 20 N/m to 300 N/m, and particularly preferably 30 N/m to 200 N/m. Generally, as the film is thicker, it is necessary to increase the tension. For example, in the case of a 100 μm film, the take-up tension is preferably 30 N/m to 150 N/m, more preferably 40 N/m to 120 N/m, and particularly preferably 50 N/m to 100 N/m.

In a case where the take-up tension is the lower limit value or more, meandering of the film during film transport can be suppressed, so that the film can be prevented from slipping and scratching during winding. In a case where the take-up tension is equal to or less than the upper limit value, it is possible to suppress vertical wrinkles from being formed in the film, and to suppress tight winding of the film to improve winding appearance. Not only that, since it is possible to suppress extension of the bump portion of the film due to creep phenomenon, flapping of the film can be suppressed. It is preferable that the take-up tension is detected by the tension control in the middle of the line as in the case of the transport tension, and the take-up tension is controlled so as to be a constant take-up tension. In a case where there is a difference in film temperature depending on the location of the film formation line, the length of the film may differ slightly due to thermal expansion, so that it is preferable to adjust a drawing ratio between the nip rolls so that the film is not tensioned more than specified in the middle of the line. In addition, with the take-up tension, the film can be wound at a constant tension by controlling the tension control, but it is more preferable to adopt a taper (changing the take-up tension as the winding diameter increases in the winding operation) according to the winding diameter to obtain an appropriate take-up tension. Generally, the tension is gradually reduced as the winding diameter is increased, but in some cases, it may be preferable to increase the tension as the winding diameter is increased. In addition, there is no problem in the winding direction regardless of which side of the first compression surface or the second compression surface is the winding core side, but in a case where the film is curled, winding it in the direction opposite to the curl has a curl correction effect and may be preferable.

It is useful to install edge position control (EPC) to control the meandering of the film during winding, perform oscillation winding to prevent the generation of winding bumps, or to use a roll which eliminates accompanying air during high-speed winding.

Winding Core

The winding core used for winding of the film does not need to be special as long as it has the strength and stiffness required to wind the film, and generally, a paper tube having an inner diameter of 3 to 6 inches or a plastic winding core having an inner diameter of 3 to 14 inches is used.

Slit

It is preferable that both ends of the formed film are slit in order to obtain a predetermined width. As a method of slitting, a general method such as a shear cut blade, a Goebel blade, a leather blade, and a rotary blade can be used. It is preferable to use a cutting method in which no dust is generated during cutting and less burr of the cut portion is generated, and cutting with a Goebel blade is preferable.

Knurling Processing

It is also preferable to perform a thickening processing (knurling treatment) on one end or both ends of the film.

A height of an unevenness due to the thickening processing is preferably 1 μm to 50 μm, more preferably 2 μm to 30 μm, and particularly preferably 3 μm to 20 μm. In the thickening processing, both sides may be convex or only one side may be convex. A width of the thickening processing is preferably 1 mm to 50 mm and particularly preferably 3 mm to 30 mm. Both cooling and heating can be used for the thickening processing, and in a case where an appropriate method is selected depending on the unevenness formed on the film or the state of dust generation during the thickening processing. It is also useful to make it possible to identify the film forming direction and the film surface by knurling processing.

Masking Film

It is also preferable to attach a lami-film (masking film) on one side or both sides in order to prevent scratches on the film or improve handleability. A thickness of the lami-film is preferably 5 μm to 100 μm, more preferably 10 μm to 70 μm, and particularly preferably 25 μm to 50 μm.

The masking film is preferably composed of two layers, a base material layer and a pressure-sensitive adhesive layer. As the base material layer, low density polyethylene (LDPE), linear low density polyethylene (LLDPE), high density polyethylene (HDPE), polypropylene (PP), polyester, and the like can be used. As the pressure-sensitive adhesive layer, ethylene vinyl acetate (EVA), acrylic rubber, styrene-based elastomer, natural rubber, and the like can be used.

Static Elimination

In a case where the film is charged, dust in the atmosphere is attracted to the film and becomes foreign matter adhering to the film. Therefore, it is preferable that the film being formed, transported, and wound is not charged.

A band voltage of the film is preferably 3 kV or less, more preferably 0.5 kV or less, and particularly preferably 0.05 kV or less.

As a method of preventing the generation of static charge on the film, various known methods such as a method of preventing the generation of static electricity by kneading or applying an antistatic agent to the film, a method of controlling the temperature and humidity of the atmosphere to suppress the generation of static electricity, a method of grounding and releasing static electricity charged on the film, and a method neutralizing with a charge having the opposite sign to the charge using an ionizer, can be used. In addition, in order to improve the effect of preventing dust from adhering to the film by static elimination, the environment at the time of film formation is preferably the US federal standard Fed. Std. 209D class 10000 or less, more preferably class 1000 or less, and particularly preferably class 100 or less.

Dust Removal

Foreign matter adhering to the film surface can be removed by a method of pressing a scraper or a brush, a method of ejecting charge-neutralized pressurized air at a pressure of several tens of KPa in order to weaken the attraction effect due to static electricity, a method by suction, or a method in which injection and suction are combined.

(Stretching and Relaxation Treatment)

Furthermore, after forming the film by the above-described method, stretching and relaxation treatment may be performed. For example, each step can be carried out by the combination of the following (a) to (g). In addition, the order of machine-direction stretching and cross-direction stretching may be reversed, each step of machine-direction stretching and cross-direction stretching may be performed in multiple stages, or diagonal stretching, simultaneous biaxial stretching, or the like may be combined.
(a) Cross-direction stretching
(b) Cross-direction stretching→relaxation treatment
(c) Machine-direction stretching
(d) Machine-direction stretching→relaxation treatment
(e) Machine-direction (cross-direction) stretching→cross-direction (machine-direction) stretching
(f) Machine-direction (cross-direction) stretching→cross-direction (machine-direction) stretching→relaxation treatment
(g) Cross-direction stretching→relaxation treatment→machine-direction stretching→relaxation treatment

Machine-Direction Stretching

The machine-direction stretching can be achieved by making the circumferential speed on the outlet side faster than the circumferential speed on the inlet side while heating between the two pairs of rolls. From the viewpoint of suppressing curling of the film, the film temperature is preferably the same on the front and back surfaces, but in a case where optical characteristics are controlled in the thickness direction, stretching can be performed at different temperatures on the front and back surfaces. The stretching temperature here is defined as the temperature on the lower side of the film surface. The machine-direction stretching step may be carried out in one step or in multiple steps. The film is generally pre-heated by passing it through a temperature-controlled heating roll, but in some cases, a heater can be used to heat the film. In addition, in order to prevent the film from pressure-sensitively adhering to the roll, a ceramic roll or the like having improved adhesiveness can also be used.

Cross-Direction Stretching

As the cross-direction stretching, ordinary cross-direction stretching can be adopted. That is, the normal cross-direction stretching is a cross-direction stretching method in which both ends of the film are gripped by clips and the clips are widened while being heated in an oven using a tenter. For example, methods described in JP1987-035817U (JP-S62-035817U), JP2001-138394A, JP1998-249934A (JP-H10-249934A), JP1994-270246A (JP-H6-270246A), JP1992-30922U (JP-H4-30922U), and JP1987-152721A (JP-S62-152721A) can be used.

A stretching temperature in the cross-direction stretching can be controlled by blowing air at a desired temperature into the tenter. The film temperature may be the same or different on the front and back surfaces for the same reason as in the machine-direction stretching step. The stretching temperature used here is defined as the temperature on the lower side of the film surface. The cross-direction stretching step may be carried out in one step or in multiple steps. In addition, in a case of performing cross-direction stretching in multiple stages, it may be performed continuously or intermittently by providing a region in which widening is not performed. For such cross-direction stretching, in addition to the normal cross-direction stretching in which the clip is widened in the width direction in the tenter, the following stretching method for gripping and widening the clip with the clip can also be applied.

Diagonal Stretching

As with normal cross-direction stretching, the clips are widened in the cross direction, but can be stretched diagonally by changing the transportation speed of the left and right clips. For example, methods described in JP2002-22944A, JP2002-086554A, JP2004-325561A, JP2008-23775A, and JP2008-110573A can be used.

Simultaneous Biaxial Stretching

The simultaneous biaxial stretching widens the clip in the cross direction and at the same time stretches or shrinks in the machine direction, similar to the normal cross-direction stretching. For example, methods described in JP1980-093520U (JP-S55-093520U), JP1988-247021A (JP-S63-247021A), JP1994-210726A (JP-H6-210726A), JP1994-278204A (JP-H6-278204A), JP2000-334832A, JP2004-106434A, JP2004-195712A, JP2006-142595A, JP2007-210306A, JP2005-022087A, JP2006-517608A, and JP2007-210306A can be used.

Improvement of Bowing (Axis Misalignment)

In the above-described cross-direction stretching step, the end part of the film is gripped by the clips. Therefore, the deformation of the film due to the thermal shrinkage stress generated during the heat treatment is large at the center portion of the film and small at the end part. As a result, the obtained film has a distribution of characteristics in the width direction. In a case where a straight line is drawn along the cross direction on the surface of the film before the heat treatment step, the straight line on the surface of the film after the heat treatment step is an arcuate shape in which the center portion is recessed toward the downstream side. This phenomenon is called a bowing phenomenon, and is a cause of disturbing isotropy and widthwise uniformity of the film.

As an improvement method, it is possible to reduce the variation in the orientation angle due to the bowing by performing preheating before such cross-direction stretching and thermal fixing after stretching. Either preheating or thermal fixing may be performed, but it is more preferable to perform both. It is preferable to perform these preheating and thermal fixing by gripping with a clip, that is, it is preferable to perform these preheating and thermal fixing continuously with the stretching.

The preheating is preferably performed at a temperature higher than the stretching temperature by approximately 1° C. to 50° C., more preferably higher than 2° C. to 40° C., and particularly preferably higher than 3° C. to 30° C. The preheating time is preferably 1 second to 10 minutes, more preferably 5 seconds to 4 minutes, and particularly preferably 10 seconds to 2 minutes.

During preheating, it is preferable to keep the width of the tenter almost constant. Here, “almost” refers to ±10% of the width of the un-stretched film.

The thermal fixing is preferably performed at a temperature lower than the stretching temperature by 1° C. to 50° C., more preferably by 2° C. to 40° C., and still more preferably by 3° C. to 30° C. Particularly preferably, the temperature is not higher than the stretching temperature and not higher than Tg of the liquid crystal polymer.

The preheating time is preferably 1 second to 10 minutes, more preferably 5 seconds to 4 minutes, and particularly preferably 10 seconds to 2 minutes. During thermal fixing, it is preferable to keep the width of the tenter almost constant. Here, “almost” means 0% (the same width as the tenter width after stretching) to −30% (30% smaller than the tenter width after stretching=reduced width) of the tenter width after the completion of stretching. In a case where the width is expanded more than the stretched width, residual strain is likely to occur in the film. Examples of other known methods include methods described in JP1889-165423A (JP-H1-165423A), JP1992-216326A (JP-H3-216326A), JP2002-018948A, and JP2002-137286A.

Thermal Relaxation Treatment

The thermal shrinkage rate can be reduced by performing a thermal relaxation treatment under the following conditions after the above-described stretching. It is preferable that the thermal relaxation treatment is carried out at at least one timing after film formation, machine-direction stretching, or cross-direction stretching. The thermal relaxation treatment may be continuously performed after the stretching, or may be performed after winding after the stretching.

(Surface Treatment)

By surface-treating the film, it is possible to improve the adhesion with the copper foil or the copper plating layer used for the copper-clad laminated board. For example, glow discharge treatment, ultraviolet irradiation treatment, corona treatment, flame treatment, or acid or alkali treatment can be used. The glow discharge treatment as mentioned herein may be a treatment with a low-temperature plasma generated in a gas at a low pressure ranging from 10⁻³ Torr to 20 Torr, and is preferably a plasma treatment under atmospheric pressure.

(Aging)

It is also useful to age the film at a temperature of Tg or lower of the liquid crystal polymer in order to improve the mechanical properties, thermal dimensional stability, or winding shape of the wound film.

(Storage Conditions)

In order to prevent wrinkles or bumps from being generated due to the relaxation of residual strain of the wound film, it is preferable to store the film in a temperature environment of Tg or lower of the liquid crystal polymer. In addition, the temperature is preferably less variable, and the temperature fluctuation per hour is preferably 30° C. or lower, more preferably 20° C. or lower, and particularly preferably 10° C. or lower. Similarly, in order to change the moisture absorption rate of the film and prevent dew condensation, a humidity is preferably 10% to 90%, more preferably 20% to 80%, and particularly preferably 30% to 70%. In order to change the moisture absorption rate of the film and prevent dew condensation, a temperature fluctuation per hour is preferably 30% or less, more preferably 20% or less, and particularly preferably 10% or less. In a case where the storage is required in a place where the temperature and humidity fluctuate, it is also effective to use a packaging material having moisture-proof or heat-insulating properties.

In the above, the film has a single layer, but may have a laminated structure in which a plurality of layers are laminated.

The manufacturing method of a liquid crystal polymer film according to the embodiment of the present disclosure may include at least one of a specific heat treatment or an annealing treatment.

(Specific Heat Treatment)

In the manufacturing method of a liquid crystal polymer film according to the embodiment of the present disclosure, it is preferable to perform a heat treatment step in which, before the molten resin which has been extruded into a sheet is solidified, the molten resin which has been extruded into a sheet is reheated using a heater, and immediately after that, the molten resin which has been extruded into a sheet is cooled using a cooler. Hereinafter, the series of heat treatments consisting of reheating and cooling performed before the molten resin which has been extruded into a sheet is solidified will also be referred to as a “specific heat treatment”.

By performing, before fixing, the specific heat treatment on the molten resin which has been extruded into a sheet, it is considered that a void area ratio in the thickness direction changes in the molten resin which has been extruded into a sheet.

Detailed mechanism by which the void area ratio in the thickness direction changes is not clear, but the present inventors presume that the change is caused by heating a film surface by a reheating treatment while the film surface is cooled immediately after the heating, so that the film-forming properties are not impaired and the crystal structure of a surface layer part of the film is changed by melting and quenching.

Conditions for the specific heat treatment are appropriately adjusted according to a material constituting the liquid crystal polymer film, a desired void area ratio, and the like.

From the viewpoint that a hardness distribution in the thickness direction can be further clarified, a temperature for the reheating is preferably, in a case where the melting point of the liquid crystal polymer is Tm (° C.), {Tm−10}° C. or higher and more preferably higher than Tm. In addition, from the viewpoint that the occurrence of thickness unevenness due to softening of the film can be suppressed, the temperature for the reheating is preferably {Tm+20}° C. or lower, and more preferably {Tm+15}° C. or lower.

A treatment time for the reheating varies depending on a heating unit and a heating temperature, but is preferably 0.2 to 15 seconds and more preferably 1 to 5 seconds.

Examples of the heating unit (heater) used for the reheating include known heating units such as a hot air dryer and an infrared heater, and the infrared heater is preferable since the film surface temperature can be elevated in a short time. It is preferable that the heating units are evenly arranged along the TD direction of the molten resin which has been extruded into a sheet. By arranging the heating units in this manner, it is possible to suppress a temperature difference in the TD direction of the molten resin which has been extruded into a sheet during the reheating.

In order to form a structure of the film surface layer and suppress the thickness unevenness, it is preferable that the cooling treatment in the specific heat treatment is performed immediately after the reheating. In the cooling treatment, it is preferable to lower the surface temperature of the molten resin which has been extruded into a sheet at a rate of −10° C./sec or more (more preferably −20° C./sec or more and still more preferably −30° C./sec or more). The upper limit thereof is not particularly limited, but is, for example, −80° C./sec or less.

From the same viewpoint as described above, it is preferable that the cooling treatment is performed until the surface temperature of the molten resin which has been extruded into a sheet is lower than a crystallization temperature. The crystallization temperature can be measured as a recrystallization peak temperature using a differential scanning calorimeter (DSC), in a case where the molten resin which has been extruded into a sheet is heated to a temperature equal to or higher than the melting point, and then cooled at 10° C./min.

A specific cooling treatment time varies depending on a cooling unit and a temperature of the film surface heated by reheating, but is preferably 0.3 to 15 seconds and more preferably 2 to 10 seconds.

As the cooling unit (cooler) used for the cooling treatment, a known cooling device can be used, but it is preferable to use a blower which blows air (preferably, cold air) on the molten resin which has been extruded into a sheet. It is preferable that the cooling units are evenly arranged along the periphery of the molten resin which has been extruded into a sheet. By arranging the cooling units in this manner, it is possible to suppress a temperature difference in the TD direction of the molten resin which has been extruded into a sheet during the cooling.

(Annealing Treatment)

In the manufacturing method according to the embodiment of the present disclosure, it is preferable that, after the specific heat treatment, an annealing treatment in which the liquid crystal polymer film is heated to near a melting temperature is performed. The annealing treatment is preferably performed after the specific heat treatment.

A reason therefor is not clear, but by performing the annealing treatment after performing the cooling treatment during the specific heat treatment (preferably, after further performing the relaxation treatment), crystallization proceeds in the surface layer region while the void regions present in the liquid crystal polymer film are smaller, a reduction in the width of the void regions in the thickness direction more remarkably occurs, and a proportion occupied by the domain region relatively increases. Aliquid crystal polymer film having the specific void characteristics described above can be manufactured by performing the cooling treatment in the specific heat treatment and the annealing treatment, and by appropriately adjusting these conditions as necessary.

A heating temperature in the annealing treatment is preferably {Tm−50}° C. to {Tm+30}° C., and more preferably higher than {Tm+10}° C. and {Tm+25}° C. or lower, with the melting point of the liquid crystal polymer being Tm (° C.). A heating time in the annealing treatment is preferably 10 seconds to 24 hours, and more preferably 4 to 12 hours. In particular, in a case where the heating temperature is Tm or lower, from the viewpoint that it is easy to manufacture a liquid crystal polymer film having the specific void characteristics described above, the heating time is more preferably 4 to 12 hours, and still more preferably 8 to 12 hours.

Examples of a heating unit in the annealing treatment include a hot-air drying furnace and a thermal press (for example, a surface press or a heating roll), and a thermal press is preferable.

The annealing treatment may be performed on a composite formed by laminating the liquid crystal polymer film on an adherend (for example, a metal foil such as a copper foil and an aluminum foil). By using the adherend, deformation of the liquid crystal polymer film during heating can be suppressed. In a case where the composite is annealed, the adherend is peeled off from the annealed composite to obtain the liquid crystal polymer film.

After the above-described annealing treatment, a thermal relaxation treatment may be further performed. The thermal relaxation step in the case is performed according to the thermal relaxation step performed before the annealing treatment described above.

[Use of Liquid Crystal Polymer Film]

The liquid crystal polymer film according to the embodiment of the present disclosure can be used in a form of a single film, a copper-clad laminated board laminated with a copper foil, a printed wiring board, a flexible printed wiring board (FPC), and the like, and can be used as a material included in a substrate for communication. That is the substrate for communication of the present disclosure has the liquid crystal polymer film according to the embodiment of the present disclosure.

The liquid crystal polymer film according to the embodiment of the present disclosure is preferably used for a flexible printed circuit board. Since the liquid crystal polymer film according to the embodiment of the present disclosure has a low relative permittivity and dielectric loss tangent, transmission loss in a high frequency band can be suppressed, which is useful. In addition, since cohesive peeling due to processing is suppressed, the liquid crystal polymer film according to the embodiment of the present disclosure is suitable for manufacturing a flexible printed circuit board.

<Laminate>

The laminate according to the embodiment of the present disclosure includes the above-described liquid crystal polymer film and at least one metal-containing layer.

Hereinafter, the configuration of the laminate according to the embodiment of the present disclosure will be described in detail.

The laminate includes at least one metal-containing layer and at least one liquid crystal polymer film. The number of the metal-containing layers and the liquid crystal polymer films included in the laminate is not limited, and the number of the respective layers may be only one or two or more.

The laminate may be a single-sided laminate having only one metal-containing layer on one side of one liquid crystal polymer film, or may be a double-sided laminate having two metal-containing layers on both sides of one liquid crystal polymer film.

Among those, it is preferable that the laminate has at least a layer configuration in which the metal-containing layer, the liquid crystal polymer film, and the metal-containing layer are laminated in this order.

In addition, the laminate may have a multi-layer structure in which three or more metal-containing layers and two or more liquid crystal polymer films are alternately laminated. That is, the laminate may have a multi-layer structure in which three or more metal layers or metal wiring lines are arranged through insulating layers consisting of the liquid crystal polymer film.

A laminate having such a multi-layer structure can be applied as a highly functional multi-layer circuit board (for example, a two-layer circuit board, a three-layer circuit board, a four-layer circuit board, and the like).

The laminate may be a monolayer circuit board provided with two metal layers or metal wiring lines and an insulating layer consisting of one liquid crystal polymer film. In addition, the laminate may be an intermediate for manufacturing a laminate having the above-described multi-layer structure, which is provided with one or two metal layers or metal wiring lines and an insulating layer consisting of one liquid crystal polymer film.

(Metal-Containing Layer)

The metal-containing layer is not particularly limited as long as it is a layer that is formed on a surface of the liquid crystal polymer film and includes a metal, and examples thereof include a metal layer covering the entire surface of the liquid crystal polymer film and a metal wiring line formed on the surface of the liquid crystal polymer film.

Examples of a material constituting the metal-containing layer include metals used for electrical connection. Examples of such metals include copper, gold, silver, nickel, aluminum, and alloys including any of these metals. Examples of the alloy include a copper-zinc alloy, a copper-nickel alloy, and a zinc-nickel alloy.

As the material constituting the metal-containing layer, copper is preferable from the viewpoint that conductivity and workability are excellent.

As the metal-containing layer, a copper layer or a copper wiring line, which includes copper or a copper alloy including 95% by mass or more of copper, is preferable. Examples of the copper layer include a rolled copper foil manufactured by a rolling method and an electrolytic copper foil manufactured by an electrolysis method. The metal-containing layer may be subjected to a chemical treatment such as pickling.

As will be described later, the metal-containing layer is produced using, for example, a metal foil, and a wiring pattern is formed by a known processing method as necessary.

In a case where a metal foil such as a copper foil is used for producing the laminate, from the viewpoint that the transmission loss is smaller in a case of being used as a flexible circuit board, a surface roughness (arithmetic average height) Ra of a surface (at least one surface) of the metal foil is preferably 2.0 μm or less, more preferably 1.0 μm or less, and still more preferably 0.5 μm or less. The lower limit value thereof is not particularly limited, but is, for example, 0.1 μm or more, preferably 0.3 μm or more.

Examples of the metal foil in which the surface roughness Ra is within the above-described range include a non-roughened copper foil, which is available on the market.

The Ra on the surface of the metal foil and the metal-containing layer is determined by a method in accordance with JIS B 0601, using a surface roughness measuring instrument (for example, manufactured by Mitutoyo Co., Ltd., product name: SurfTest SJ-201). A specific measuring method therefor will be described in Examples later.

A thickness of the metal-containing layer is not particularly limited and is appropriately selected depending on a use of the circuit board, but from the viewpoint of wiring line conductivity and economical efficiency, it is preferably 1 to 100 μm, more preferably 5 to 30 μm, and still more preferably 10 to 20 μm.

The laminate may include a layer other than the liquid crystal polymer film and the metal-containing layer as necessary. Examples of other layers include an adhesive layer, a rust preventive layer, and a heat resistant layer.

(Adhesive Layer)

From the viewpoint that the peel strength is more excellent, the laminate preferably includes an adhesive layer.

In a case where the laminate includes an adhesive layer, the adhesive layer is preferably disposed between the liquid crystal polymer film and the metal-containing layer. For example, in a case where two metal-containing layers are arranged on both sides of the liquid crystal polymer film, it is preferable that the metal-containing layer, the adhesive layer, the liquid crystal polymer film, the adhesive layer, and the metal-containing layer are laminated in this order.

As the adhesive layer, a known adhesive layer used for manufacturing a wiring board such as a copper-clad laminate can be used, and examples thereof include a layer which includes a cured product of an adhesive composition including at least one of a known binder resin or a reactive compound described later.

The adhesive composition used for forming the adhesive layer is not particularly limited, and examples thereof include a composition which includes a binder resin and/or a reactive compound, and further includes an additive described later as an optional component.

(Binder Resin)

Examples of the binder resin include a (meth)acrylic resin, a polyvinyl cinnamate, a polycarbonate, a polyimide, a polyamidoimide, a polyesterimide, a polyetherimide, a polyether ketone, a polyether ether ketone, a polyethersulfone, a polysulfone, a polyparaxylene, a polyester, a polyvinyl acetal, a polyvinyl chloride, a polyvinyl acetate, a polyamide, a polystyrene, a polyurethane, a polyvinyl alcohol, a cellulose acylate, a fluororesin, a liquid crystal polymer, a syndiotactic polystyrene, a silicone resin, an epoxy silicone resin, a phenol resin, an alkyd resin, an epoxy resin, a maleic acid resin, a melamine resin, a urea resin, an aromatic sulfonamide, a benzoguanamine resin, a silicone elastomer, an aliphatic polyolefin (for example, polyethylene and polypropylene), and a cyclic olefin copolymer. Among those, a polyimide, a liquid crystal polymer, a syndiotactic polystyrene, or a cyclic olefin copolymer is preferable, and a polyimide is more preferable.

The binder resin may be used alone or in combination of two or more kinds thereof.

A content of the binder resin is preferably 60% to 99.9% by mass, more preferably 70% to 99.0% by mass, and still more preferably 80% to 97.0% by mass with respect to the total mass of the adhesive layer.

(Reactive Compound)

The adhesive layer may include a reaction product of a compound having a reactive group, and preferably further includes a reactive compound in addition to the binder resin. In the present specification, the compound having a reactive group and the reaction product thereof are also collectively referred to as a “reactive compound”.

The reactive group included in the reactive compound is preferably a group capable of reacting with a group which may be present on a surface of the liquid crystal polymer film (in particular, a group having an oxygen atom, such as a carboxy group and a hydroxy group).

Examples of the reactive group include an epoxy group, an oxetanyl group, an isocyanate group, an acid anhydride group, a carbodiimide group, an N-hydroxyester group, a glyoxal group, an imide ester group, an alkyl halide group, and a thiol group; and at least one group selected from the group consisting of an epoxy group, an acid anhydride group, and a carbodiimide group is preferable, and an epoxy group is more preferable.

Specific examples of the reactive compound having an epoxy group include aromatic glycidylamine compounds (for example, N,N-diglycidyl-4-glycidyloxyaniline, 4,4′-methylenebis(N,N-diglycidylaniline), N,N-diglycidyl-o-toluidine, and N,N,N′,N′-tetraglycidyl-m-xylene diamine, 4-t-butylphenylglycidyl ether), aliphatic glycidylamine compounds (for example, 1,3-bis(diglycidylaminomethyl)cyclohexane), and aliphatic glycidyl ether compounds (for example, sorbitol polyglycidyl ether).

Specific examples of the reactive compound having an acid anhydride group include tetracarboxylic dianhydrides (for example, 3,3′,4,4′-benzophenone tetracarboxylic dianhydride, 3,3′,4,4′-biphenyltetracarboxylic dianhydride, pyromellitic dianhydride, 2,3,3′,4′-biphenyltetracarboxylic dianhydride, oxydiphthalic dianhydride, diphenylsulfone-3,4,3′,4′-tetracarboxylic dianhydride, bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenone tetracarboxylic dianhydride, bis(3,4-dicarboxyphenyl)methane dianhydride, 2,2-bis(3,4-dicarboxyphenyl)propane dianhydride, p-phenylenebis(trimellitic acid monoester anhydride), p-biphenylenebis(trimellitic acid monoester anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride, 2,3,6,7-naphthalenetetracarboxylic dianhydride, 1,4,5,8-naphthalenetetracarboxylic dianhydride, and 4,4′-(2,2-hexafluoroisopropyridene)diphthalic dianhydride).

Specific examples of the reactive compound having a carbodiimide group include monocarbodiimide compounds (for example, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, N,N′-di-2,6-diisopropylphenylcarbodiimide), and polycarbodiimide compounds (for example, compounds produced by the methods described in U.S. Pat. No. 2,941,956A, JP1972-033279B (JP-S47-033279B), J. Org. Chem. 28, pp. 2069 to 2075 (1963), Chemical Review 1981, 81, No. 4, pp. 619 to 621, and the like).

Examples of a commercially available product of the reactive compound having a carbodiimide group include Carbodilite (registered trademark) HMV-8CA, LA-1, and V-03 (all manufactured by Nisshinbo Chemical Inc.), and Stabaxol (registered trademark) P, P100, and P400 (all manufactured by Rhein Chemie Japan Ltd.), and Stabilizer 9000 (product name, manufactured by Rhein Chemie Corporation).

The number of reactive groups included in the reactive compound is 1 or more, but from the viewpoint that adhesiveness between the liquid crystal polymer film and the metal-containing layer is more excellent, it is preferably 2 or more. That is, the reactive compound is preferably a crosslinking agent having two or more reactive groups. The number of reactive groups included in the crosslinking agent is more preferably 3 or more. The upper limit of the number of reactive groups included in the reactive compound or the crosslinking agent is not particularly limited, but is, for example, 6 or less, preferably 5 or less. Examples of the reactive group included in the crosslinking agent include the above-mentioned preferred reactive groups.

The reaction product of the compound having a reactive group is not particularly limited as long as it is a compound derived from the compound having a reactive group, and examples thereof include a reaction product obtained by a reaction between the reactive group of the compound having a reactive group and a group including an oxygen atom, present on the surface of the liquid crystal polymer film.

The reactive compound may be used alone or in combination of two or more kinds thereof.

A content of the reactive compound is preferably 0.1% to 40% by mass, more preferably 1% to 30% by mass, and still more preferably 3% to 20% by mass with respect to the total mass of the adhesive layer.

The adhesive layer may further include a component (hereinafter also referred to as an “additive”) other than the binder resin and the reactive compound.

Examples of the additive include an inorganic filler, a curing catalyst, and a flame retardant.

A content of the additive is preferably 0.1% to 40% by mass, more preferably 1% to 30% by mass, and still more preferably 3% to 20% by mass with respect to the total mass of the adhesive layer.

(Thickness)

In a case where the laminate includes an adhesive layer, from the viewpoint that the peel strength of the metal-containing layer is more excellent, a thickness of the adhesive layer is preferably 0.05 μm or more, more preferably 0.1 μm or more, and still more preferably 0.2 μm or more. The upper limit thereof is not particularly limited, but is preferably 1 μm or less, more preferably 0.8 μm or less, and still more preferably 0.6 μm or less.

In addition, from the viewpoint that the peel strength of the metal-containing layer is more excellent, a ratio of the thickness of the adhesive layer to the thickness of the liquid crystal polymer film is preferably 0.1% to 2%, and more preferably 0.2% to 1.6%.

The above-described thickness of the adhesive layer is a thickness per adhesive layer.

The thickness of the adhesive layer can be measured according to the method for measuring the thickness of the liquid crystal polymer film described above.

<Manufacturing Method of Laminate>

A manufacturing method of the laminate is not particularly limited, and examples thereof include a method having a step of laminating the liquid crystal polymer film according to the embodiment of the present disclosure and a metal foil, and then compressing the liquid crystal polymer film and the metal foil under high-temperature conditions to manufacture the laminate (hereinafter, referred to as a “step B”).

(Step B)

In the step B, the liquid crystal polymer film according to the embodiment of the present disclosure and a metal foil consisting of a metal constituting the metal-containing layer are laminated, and the liquid crystal polymer film and the metal foil are compressed under high-temperature conditions to manufacture the laminate having the liquid crystal polymer film and the metal-containing layer.

The liquid crystal polymer film and the metal foil used in the step B are as described above. Methods and conditions for the thermocompression of the liquid crystal polymer film and the metal foil in the step B are not particularly limited, and are appropriately selected from known methods and conditions.

The thermocompression in the step B can be performed by using a known unit such as a heating roll. Examples of the heating roll include a metal roll and a heat-resistant rubber roll.

The temperature condition for the thermocompression is preferably {Tm−80}° C. to {Tm+30}° C., and more preferably {Tm−40}° C. to Tm° C. The pressure condition for the thermocompression is preferably 0.1 to 20 MPa. A treatment time of the compression treatment is preferably 0.001 to 1.5 hours.

The metal-containing layer provided in the laminate may be a patterned metal wiring line. A method for producing the metal wiring line is not particularly limited, and examples thereof include a method in which the above-described metal wiring line is formed by performing the step B in which the liquid crystal polymer film and the metal foil are laminated by thermocompression, and then a metal layer thus formed is subjected to an etching treatment and the like. In addition, the patterned metal wiring line may be directly formed on the surface of the liquid crystal polymer film by a known method such as a sputtering method, an ion plating method, a vapor phase method such as a vacuum vapor deposition method, and a wet plating method.

<Adhesive Layer Forming Step>

In a case where the laminate including the liquid crystal polymer film, the adhesive layer, and the metal-containing layer in this order is manufactured, the laminate including the adhesive layer can be obtained by performing a step of forming the adhesive layer on at least one of the liquid crystal polymer films using an adhesive composition, and then performing the step B using the liquid crystal polymer film with the adhesive layer and the metal foil.

Examples of the adhesive layer forming step include a step in which an adhesive composition is applied onto at least one surface of the liquid crystal polymer film, and the coating film is dried and/or cured as necessary to form the adhesive layer on the liquid crystal polymer film.

Examples of the adhesive composition include a composition which includes components constituting the adhesive layer, such as the binder resin, the reactive compound, and the additive, which are described above, and includes a solvent. Since the components constituting the adhesive layer are as described above, descriptions thereof will be omitted.

Examples of the solvent (organic solvent) include ester compounds (for example, ethyl acetate, n-butyl acetate, and isobutyl acetate), ether compounds (for example, ethylene glycol dimethyl ether, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, and diethylene glycol monoethyl ether), ketone compounds (for example, methyl ethyl ketone, cyclohexanone, cyclopentanone, 2-heptanone, and 3-heptanone), hydrocarbon compounds (hexane, cyclohexane, and methylcyclohexane), and aromatic hydrocarbon compounds (for example, toluene and xylene).

The solvent may be used alone or in two or more kinds thereof.

A content of the solvent is, for example, preferably 0.0005% to 0.02% by mass, and more preferably 0.001% to 0.01% by mass with respect to the total mass of the adhesive composition.

A solid content of the adhesive composition is preferably 99.98% to 99.9995% by mass, and more preferably 99.99% to 99.999% by mass with respect to the total mass of the adhesive composition.

In the present specification, the “solid content” of a composition means components excluding the solvent (organic solvent) and water. That is, the solid content of the adhesive composition is intended to be components constituting the adhesive layer, such as the binder resin, the reactive compound, and the additive described above.

A method for adhering the adhesive composition on the liquid crystal polymer film is not particularly limited, and examples thereof include a bar coating method, a spray coating method, a squeegee coating method, a flow coating method, a spin coating method, a dip coating method, a die coating method, an ink jet method, and a curtain coating method.

In a case where the adhesive composition adhered on the liquid crystal polymer film is dried, drying conditions are not particularly limited, but the drying temperature is preferably 25° C. to 200° C. and the drying time is preferably 1 second to 120 minutes.

In the manufacturing method of the laminate, the laminate of the present disclosure can be produced by performing a step of forming the adhesive layer using the adhesive composition, then laminating the liquid crystal polymer film and the metal-containing layer (with the adhesive layer), and performing the above-described step B in which the liquid crystal polymer film and the metal foil are thermo-compressed.

The method for manufacturing the laminate of the present disclosure, including the liquid crystal polymer film and the metal-containing layer, is not limited to the method described above.

For example, a laminate in which a liquid crystal polymer film, an adhesive layer, and a metal-containing layer are laminated in this order can be manufactured by applying the adhesive composition onto at least one surface of a metal foil; drying and/or curing the coating film as necessary to form the adhesive layer; laminating the metal foil with the adhesive layer and the liquid crystal polymer film so that the adhesive layer is in contact with the liquid crystal polymer film; and subjecting the metal foil, the adhesive layer, and the liquid crystal polymer film to thermocompression according to the method described in the step B.

In addition, the laminate may be produced by forming the metal-containing layer on a surface of the liquid crystal polymer film by a known method such as deposition, electroless plating, and electrolytic plating.

The laminate manufactured by the above-described can be used in the manufacturing of the above-described multi-layer circuit board.

For example, a circuit board having a multi-layer structure can be manufactured by subjecting the metal layer provided in a laminate (first laminate) manufactured by the above-described manufacturing method to a patterning step as necessary to form a metal wiring line; laminating the first laminate having the metal wiring line and a second laminate formed by sticking a metal layer onto one surface of an insulating layer including the liquid crystal polymer film so that a surface of the first laminate on the metal wiring line side and a surface of the second laminate on the insulating layer side are in contact with each other; and subjecting a laminate thus obtained to thermocompression in accordance with the above-described step B.

<Flexible Copper-clad Laminated Board>

An example of the laminate of the present disclosure is a flexible copper-clad laminated board.

The flexible copper-clad laminated board according to the embodiment of the present disclosure includes the above-described liquid crystal polymer film, and a copper foil disposed on at least one surface of the above-described liquid crystal polymer film.

The flexible copper-clad laminated board according to the embodiment of the present disclosure can be manufactured by forming an adhesive layer on one side or both sides of the liquid crystal polymer film, and laminating the liquid crystal polymer film and the copper foil through the adhesive layer. As an adhesive constituting the adhesive layer, a known adhesive can be used.

The copper foil may be either a rolled copper foil formed by a rolling method or and an electrolytic copper foil formed by an electrolysis method, but from the viewpoint of bend resistance, a rolled copper foil is preferable.

A thickness of the copper foil is not particularly limited, but is preferably 3 μm to 15 μm and more preferably 5 μm to 10 μm. The copper foil may be a copper foil with a carrier, which is formed on a support (carrier) and can be peeled off. As the carrier, a known carrier can be used. A thickness of the carrier is not particularly limited, but is preferably 10 μm to 100 μm and more preferably 18 μm to 50 μm.

<Flexible Printed Circuit Board>

The flexible printed circuit board according to the embodiment of the present disclosure is formed by processing the copper foil in the above-described flexible copper-clad laminated board. Specifically, it is preferable that the flexible printed circuit board according to the embodiment of the present disclosure is manufactured by etching the copper foil in the above-described flexible copper-clad laminated board to form a desired circuit pattern.

### EXAMPLES

Hereinafter, the present invention will be described in more detail using examples. However, the present invention is not limited to the following examples as long as it does not depart from the gist of the present invention.

### Example 1

(Pelletizing Step)

As a liquid crystal polymer, a thermotropic liquid crystal polyester (product name “LAPEROS C-950”, melting point: 320° C.; see Formula (I) below) manufactured by Polyplastics Co., Ltd. was used.

The liquid crystal polymer was charged into a reaction container provided with a thermometer (thermoelectric pair), a dehydration tube, a nitrogen introduction pipe, and a stirring device (stirring blade). After putting the reaction container in an oil bath, the inside of the reaction container was replaced with a nitrogen atmosphere. While stirring the content in the reaction container, the temperature in the reaction container was raised to 280° C. using the oil bath. The liquid crystal polymer in the reaction container was heat-treated for 480 minutes, and then the liquid crystal polymer was taken out from the reaction container and cooled to obtain a liquid crystal polymer after the heat treatment.

10 parts by mass of an ethylene-glycidyl methacrylate copolymer (product name: Bondfast BF-2C, manufactured by Sumitomo Chemical Co., Ltd.) was added to 90 parts by mass of the liquid crystal polymer after the heat treatment, and the mixture was kneaded and pelletized using a biaxial extruder. A barrel temperature of the biaxial extruder during kneading and pelletizing was set to 330° C., and a shear rate of the biaxial extruder during kneading and pelletizing (hereinafter, also referred to as a “shear rate (pelletization)”) was set to 300 sec⁻¹.

Using a dehumidifying hot air dryer, the kneaded pellets were dried at 80° C. for 12 hours by aerating the kneaded pellets with air with a dew point temperature of −45° C. Amoisture content in the kneaded pellets was set to 50 ppm by mass or less.

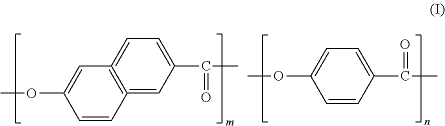

(in Formula (I), m and n represent a molar ratio of the constitutional unit, and m:n=77:23)

[Film Forming Step]

100 parts by mass of the dried kneaded pellets, 0.1 parts by mass of a solid lubricant (stearic acid), and 0.1 parts by mass of a solid heat stabilizer (irganox 1010 (manufactured by BASF)) were supplied into a cylinder from the same supply port of a biaxial extruder having a screw diameter of 50 mm, and heated and kneaded at 340° C. to 350° C. to obtain a kneaded material. Thereafter, a film-like kneaded material in a molten state was discharged from a T-die having a die width of 750 mm and a slit spacing of 300 μm. A time from that the kneaded material passed through the biaxial extruder until the film-like kneaded material was discharged from the T-die (hereinafter, also referred to as a “retention time (during film formation)”) was set to 8 minutes.

A thickness unevenness in a width direction of the film was improved by finely adjusting a clearance of a die lip portion. In this way, a liquid crystal polymer film of Example 1, having a thickness of 100 μm, was obtained.

The thickness of the liquid crystal polymer film was measured using a contact type thickness meter (manufactured by Mitutoyo Corporation). An arithmetic average value of the thicknesses of the liquid crystal polymer film at 100 different points was obtained and used as the thickness of the liquid crystal polymer film.

### Example 2

A liquid crystal polymer film of Example 2 was obtained in the same manner as in Example 1, except that the heat treatment time of the liquid crystal polymer was changed to 840 minutes.

### Example 3

A liquid crystal polymer film of Example 3 was obtained in the same manner as in Example 1, except that the extruder barrel temperature in the kneading pelletization step was changed to 350° C.

### Example 4

A liquid crystal polymer film of Example 4 was obtained in the same manner as in Example 1, except that the heat treatment time of the liquid crystal polymer was changed to 240 minutes.

### Example 5

A liquid crystal polymer film of Example 5 was obtained in the same manner as in Example 1, except that the heat treatment time of the liquid crystal polymer was changed to 1200 minutes.

### Example 6

A liquid crystal polymer film of Example 6 was obtained in the same manner as in Example 1, except that the heat treatment time of the liquid crystal polymer was changed to 600 minutes.

### Example 7

A liquid crystal polymer film of Example 7 was obtained in the same manner as in Example 1, except that the heat treatment time of the liquid crystal polymer was changed to 550 minutes.

### Example 8

A liquid crystal polymer film was obtained in the same manner as in Example 1, except that the heat treatment time of the liquid crystal polymer was changed to 1320 minutes.

### Example 9

A liquid crystal polymer film was obtained in the same manner as in Example 1, except that the heat treatment time of the liquid crystal polymer was changed to 3000 minutes.

### Comparative Example 1

A liquid crystal polymer film of Comparative Example 1 was obtained in the same manner as in Example 1, except that the heat treatment time of the liquid crystal polymer was not performed.

### Comparative Example 2

A liquid crystal polymer film of Comparative Example 2 was obtained in the same manner as in Example 1, except that the heat treatment time of the liquid crystal polymer was changed to 60 minutes.

### Comparative Example 3

A liquid crystal polymer film was obtained in the same manner as in Example 1, except that the heat treatment time of the liquid crystal polymer was changed to 3240 minutes.

<Evaluation>

(Evaluation of Tear Strength)

From the liquid crystal polymer films obtained in each of Examples, five test pieces which had been cut out with a dimension of 75 mm in the TD direction of the liquid crystal polymer film and 63 mm in the MD direction of the liquid crystal polymer film were produced. Tear strength of the obtained test pieces was measured in accordance with JIS 7128-2: 1998.

A slit of the test piece was inserted in a direction corresponding to the MD direction of the liquid crystal polymer film.

(Evaluation of Film-Forming Properties)

In the film forming step of each of Examples, a state in which the film-like kneaded material was discharged from the T-die was visually confirmed and evaluated according to the following evaluation standard.

—Evaluation Standard—

A: No film breakage or holes were generated in a case where the kneaded material was discharged from the T-die, and there was no visually confirmed unevenness on the surface of the obtained liquid crystal polymer film.

B: No film breakage or holes were generated in a case where the kneaded material was discharged from the T-die, but there was visually confirmed unevenness on the surface of the obtained liquid crystal polymer film.

C: Film breakage or holes were generated in a case where the kneaded material was discharged from the T-die, and the obtained liquid crystal polymer film was not suitable for practical use.

Table 1 shows the melting point, the number-average molecular weight, the melt viscosity, and the amount of heat of crystal melting of the liquid crystal polymer film obtained in each of Examples, and various evaluation results.

The melting point, the number-average molecular weight, the melt viscosity, and the amount of heat of crystal melting of the liquid crystal polymer film were measured as described above.

TABLE 1

| | Flim | | | | | | |
|---|---|---|---|---|---|---|---|
| | formation | Liquid crystal polymer film | | | | Evaluation | |
| | step | Melting | | Melt | Amount of | Tear | |
| | Type of | point | Number-average | viscosity | heat of crystal | strength | Film-forming |
| | die | (° C.) | molecular weight | (Pa · s) | melting (J/g) | (g/f) | properties |
| Example 1 | T-die | 327 | 14000 | 134 | 1.1 | 27 | B |
| Example 2 | T-die | 326 | 20000 | 211 | 1.6 | 39 | B |
| Example 3 | T-die | 325 | 20000 | 206 | 0.7 | 40 | A |
| Example 4 | T-die | 325 | 13000 | 102 | 1.4 | 5 | B |
| Example 5 | T-die | 328 | 35000 | 303 | 1.7 | 50 | B |
| Example 6 | T-die | 325 | 17000 | 155 | 1.4 | 30 | B |
| Example 7 | T-die | 325 | 16000 | 145 | 1.5 | 29 | B |
| Example 8 | T-die | 328 | 36000 | 320 | 0.9 | 49 | B |
| Example 9 | T-die | 330 | 150000 | 380 | 1.9 | 70 | B |
| Comparative | T-die | 325 | 11000 | 71 | 0.2 | 18 | B |
| Example 1 | | | | | | | |
| Comparative | T-die | 325 | 12000 | 92 | 0.7 | 20 | B |
| Example 2 | | | | | | | |
| Comparative | T-die | 330 | 160000 | 385 | 1.5 | 78 | C |
| Example 3 | | | | | | | |

From the above results, it was found that the liquid crystal polymer film of the present example has high tear resistance and excellent film-forming properties.

### Example 101

Manufacturing of Liquid Crystal Polymer Film

A liquid crystal polymer film was obtained in the same manner as in Example 1, except that the pelletizing step and the film forming step were performed according to the following procedure.

(Pelletizing Step)

Kneaded pellets were obtained in the same manner as in Example 1, except that the heat treatment time of the liquid crystal polymer was changed to 2400 minutes.

(Film Forming Step)

100 parts by mass of the dried kneaded pellets, 0.1 parts by mass of a solid lubricant (stearic acid), and 0.1 parts by mass of a solid heat stabilizer (irganox 1010 (manufactured by BASF)) were supplied into a cylinder from the same supply port of a biaxial extruder having a screw diameter of 50 mm, and heated and kneaded at 340° C. to 350° C. to obtain a kneaded material. Thereafter, a film-like kneaded material in a molten state was discharged from a T-die having a die width of 750 mm and a slit spacing of 300 μm. A time from that the kneaded material passed through the biaxial extruder until the film-like kneaded material was discharged from the T-die (hereinafter, also referred to as a “retention time (during film formation)”) was set to 8 minutes. A thickness unevenness in a width direction of the film was improved by finely adjusting a clearance of a die lip portion.

A specific heat treatment of heating and immediately cooling was performed on the film-like kneaded material discharged from the T-die.

More specifically, as the specific heat treatment, using an infrared heater disposed directly below the T-die, heating was performed for 2 seconds so that a surface temperature of the film-like kneaded material reached 330° C. Immediately after that, using a cold air nozzle disposed directly below the infrared heater, cooling was performed for 2 seconds so that the surface temperature of the film-like kneaded material decreased at a cooling rate of −50° C./sec.

Next, the film-like kneaded material subjected to the specific heat treatment was wound up in a form of a film.

Next, the wound film was subjected to an annealing treatment by introducing the film into a hot-air drying furnace set at 350° C. and heating for 1 hour.

The film after the annealing treatment was transported while being guided by a roller, and taken up by a nip roller to obtain the liquid crystal polymer film. A thickness of the manufactured liquid crystal polymer film was 50 μm.

Manufacture of Metal-Clad Laminate (Step B)

The liquid crystal polymer film manufactured in the above-described step and two copper foils 1 described below were laminated, and the laminate was introduced between a heat-resistant rubber roll and a heating metal roll provided in a continuous thermal press machine, and then compressed, thereby producing a copper-clad laminate in which the copper foil 1, the liquid crystal polymer film, and the copper foil 1 were laminated in this order.

As the above-described heat-resistant rubber roll, a resin-coated metal roll (manufactured by Yuri Roll Machine Co., Ltd., product name: Super-Tempex, resin thickness: 1.7 cm) was used. In addition, as the heat-resistant rubber roll and the heating metal roll, rolls having a diameter of 40 cm were used.

Surface temperatures of the heating metal roll and the heat-resistant rubber roll were set to 260° C. Furthermore, pressures applied to the liquid crystal polymer film and the copper foils 1 between the heat-resistant rubber roll and the heating metal roll were set to 120 kg/cm² in terms of a surface pressure.

(Metal Foil)

The following metal foil was used in the manufacture of the metal-clad laminate.

Copper foil 1: Rolled copper foil, thickness of 12 μm, surface roughness Ra of 0.9 μm A surface roughness Ra of the copper foil could be calculated by measuring values of an arithmetic average roughness Ra at ten points on a surface of the copper foil in accordance with JIS B0601, using a surface roughness measuring instrument (manufactured by Mitutoyo Co., Ltd., product name: SurfTest SJ-201), and by averaging the measured values.

### Example 102

Manufacturing of Liquid Crystal Polymer Film

A liquid crystal polymer film and a copper-clad laminate were obtained in the same manner as in Example 101, except that the specific heat treatment was not performed.

### Example 103

Manufacturing of Liquid Crystal Polymer Film

A liquid crystal polymer film and a copper-clad laminate were obtained in the same manner as in Example 101, except that the annealing treatment was not performed.

### Example 104

Manufacturing of Liquid Crystal Polymer Film

A liquid crystal polymer film and a copper-clad laminate were obtained in the same manner as in Example 101, except that the specific heat treatment and the annealing treatment were not performed.

Table 2 shows the melting point, the number-average molecular weight, the melt viscosity, and the amount of heat of crystal melting of the liquid crystal polymer film obtained in each of Examples, and various evaluation results.

The melting point, the number-average molecular weight, the melt viscosity, and the amount of heat of crystal melting of the liquid crystal polymer film were measured as described above.

<Elastic Modulus>

An elastic modulus of the liquid crystal polymer film manufactured in each of Examples was measured by the following method.

The liquid crystal polymer film manufactured in each of Examples was cut along the thickness direction to produce a cut surface. With regard to the obtained cut surface, an elastic modulus A at a position A at a distance of half of a thickness of the liquid crystal polymer film from one surface toward the other surface of the liquid crystal polymer film and an elastic modulus B at a position B at a distance of ⅛ of the thickness of the liquid crystal polymer film from one surface toward the other surface of the liquid crystal polymer film were measured by a nanoindentation method.

The elastic modulus was measured at ten points for each position, using a nanoindenter (“TI-950”, manufactured by HYSITRON Inc.) and a Berkovich indenter under the conditions of a load of 500 N, a load time of 10 seconds, a holding time of 5 seconds, and an unloading time of 10 seconds. An arithmetic average value of the ten points was taken as the elastic modulus (unit: GPa) for each position.

The elastic modulus A at the position A, the elastic modulus B at the position B, and the ratio (ratio B/A) of the elastic modulus B to the elastic modulus A are each shown in Table 2 described later.

<Dielectric Characteristics>

A center portion of the liquid crystal polymer film manufactured in each of Examples was sampled, and a dielectric loss tangent and a relative permittivity in a frequency band of 28 GHz were measured in an environment at a temperature of 23° C. and a humidity of 50% RH, using a split cylinder type resonator (“CR-728” manufactured by Kanto Electronics Application & Development, Inc.) and a network analyzer (Keysight N5230A).

<Void Regions of Liquid Crystal Polymer Film>

Void regions of the liquid crystal polymer film manufactured in each of Examples was measured by the following method.

The liquid crystal polymer film manufactured in each of Examples was cut along the thickness direction at room temperature (25° C.), using a microtome diamond knife. The liquid crystal polymer film having an exposed cross section was immersed in monomethylamine at room temperature (25° C.) for 4 hours, distilled water was dropped on the cross section to wash the liquid crystal polymer film, and the water droplets were removed with an air duster. Thereafter, the cross section of the liquid crystal polymer film was imaged using a scanning electron microscope (SEM) (“S-4800 type” manufactured by Hitachi High-Tech Fielding Corporation) at an acceleration voltage of 2 kV and a magnification of 3,000 times.

The captured image was binarized using a Threshold function of image processing software “ImageJ”, and the image was divided into a dark portion and a bright portion to obtain image processing data. A threshold value in the binarization was automatically determined by the image processing software, between 88 gradation to 105 gradation of 256 gradations according to a contrast of the captured image. A range of the captured image was 15 μm in the thickness direction×42 μm in the transport direction. The dark portion in the binarized image processing data corresponds to the void regions of the liquid crystal polymer film.

An area of the dark portion was automatically detected and measured from the binarized image processing data, and an area of each void region was determined from the obtained measured value and an average area of the void regions was determined. Next, the dark portion in the binarized image processing data was thinned using a thinning processing function of the above-described image processing software, and a length of each dark portion was automatically detected and measured. For each void region, an average length of the voids was calculated from the data automatically detected and measured. An average value of the widths of the void regions was calculated by dividing the average area of the obtained void regions by the average length of the obtained void regions.

In addition, the captured image of the above-described cross section was divided into each region of a first surface layer region having a distance of 5 μm or less from one surface, a second surface layer region having a distance of 5 μm or less from the other surface, a central layer region within 2.5 μm from a center line equidistant from both surfaces, binarized data was acquired from a captured image of n=2, and an area ratio (void area ratio) of the void regions in each region was calculated.

Each void area ratio means a proportion (%) of the total area of voids in each region to an area of each region of the cross section of the liquid crystal polymer film. At the same time as the above-described void area ratio, an area ratio of the void regions in the entire thickness direction of the cross section of the liquid crystal polymer film was calculated.

<Void Area Proportion X and Void Area Proportion Y>

A void area proportion of the liquid crystal polymer film manufactured in each of Examples was measured by the following method.

The liquid crystal polymer film manufactured in each of Examples was cut along the thickness direction at room temperature (25° C.), using a microtome diamond knife. The liquid crystal polymer film having an exposed cross section was immersed in monomethylamine at room temperature (25° C.) for 4 hours, distilled water was dropped on the cross section to wash the liquid crystal polymer film, and the water droplets were removed with an air duster. Thereafter, the cross section of the liquid crystal polymer film was imaged using a scanning electron microscope (SEM) (“S-4800 type” manufactured by Hitachi High-Tech Fielding Corporation) at an acceleration voltage of 2 kV and a magnification of 3,000 times.

The captured image was binarized using a Threshold function of image processing software “ImageJ”, and the image was divided into a dark portion and a bright portion to obtain image processing data. A threshold value in the binarization was automatically determined by the image processing software, between 88 gradation to 105 gradation of 256 gradations according to a contrast of the captured image. A range of the captured image was 15 μm in the thickness direction×42 μm in the transport direction. The dark portion in the binarized image processing data corresponds to the void regions of the liquid crystal polymer film.

An area of the dark portion was automatically detected and measured from the binarized image processing data, and an area of each void region was determined from the obtained measured value and an average area of the void regions was determined.

From one surface toward the other surface of the liquid crystal polymer film, a position at a distance of 1/10 of a thickness of the liquid crystal polymer film was defined as a position T1, a position at a distance of 4/10 of the thickness of the liquid crystal polymer film was defined as a position T2, and a position at a distance of 6/10 of the thickness of the liquid crystal polymer film was defined as a position T3; and a region from the one surface to the position T1 was defined as an S region and a region from the position T2 to the position T3 was defined as a C region. Thereafter, binarized data were obtained from a captured image with n=2, and a void area proportion X which was a void area proportion in the S region and a void area proportion Y which was a void area proportion in the C region were calculated. Each void area proportion means a proportion (%) of the area of voids in each region with respect to the area of each region of the cross section of the liquid crystal polymer film.

The values of “Void area proportion Y−Void area proportion X” (described as (Y−X) in the tables) are shown in Table 2 described later.

<Hardness>

A hardness of the liquid crystal polymer film manufactured in each of Examples was measured by the following method.

The liquid crystal polymer film manufactured in each of Examples was embedded with an epoxy resin, cut along the thickness direction of the embedded liquid crystal polymer film, and the exposed cross section was ground with a microtome to obtain a cut surface for measurement. In the obtained cut surface, a hardness A at a position A at a distance of half of a thickness of the liquid crystal polymer film from one surface toward the other surface of the liquid crystal polymer film and a hardness B at a position B at a distance of 1/10 of a thickness of the liquid crystal polymer film from one surface to the other surface of the liquid crystal polymer film in a cross section along a thickness direction of the liquid crystal polymer film were measured by a nanoindentation method.

The measurement was performed according to IS014577, specifically using TI-950 (Nanotriboindenter) (manufactured by Bruker Japan Co., Ltd.) with a Belkovic indenter, the measurement was performed at six points for each position under the condition of an indentation load of 500 μN, and an arithmetic average value at the six points was defined as the hardness (unit: GPa).

The values of “(Hardness A+Hardness B)/2” (described as (A+B)/2 in the tables) and the values of “Hardness A−Hardness B” (described as (A−B) in the tables) are each shown in Table 2 described later.

<Linear Expansion Coefficiency>

A linear expansion coefficiency of the liquid crystal polymer film manufactured in each of Examples was measured by the following method.

A sample with a width of 6 mm and a length of 6 mm was cut from the center portion of the liquid crystal polymer film manufactured in each of Examples, the sample was placed on a sample stage of a thermomechanical analyzer (“TMA-Q400” manufactured by TA Instruments Japan), and then an in-plane linear expansion coefficiency (CTE) of the liquid crystal polymer film was measured.

<Evaluation>

Table 3 shows results of the following evaluations.

(Evaluation of Tear Strength and Evaluation of Film-Forming Properties)

The tear strength and the film-forming properties were evaluated according to the procedures described above.

(Adhesiveness)

A copper-clad laminate produced in each of Examples was cut into strips of 1 cm×5 cm to produce a sample for evaluation of adhesiveness. A peel strength (unit: N/cm) of the obtained sample was measured according to the method for measuring a peel strength of a flexible printed wiring board, described in JIS C 5016-1994. An adhesiveness measurement test was carried out by peeling the copper foil at a peeling rate of 50 mm/min in a direction at an angle of 900 with respect to a copper foil removal surface, using a tensile tester (manufactured by IMADA Co., Ltd., Digital Force Gauge ZP-200N). The adhesiveness between the metal foil and the liquid crystal polymer film was evaluated based on the value measured by the tensile tester.

(Misregistration)

The double-sided copper-clad laminate produced in each of Examples was cut into a size of 15 cm×15 cm to produce a sample of the double-sided copper-clad laminate. A mask layer was laminated on a surface of one of the copper layers of the obtained sample, and the mask layer was exposed in a patterned manner and then developed to form a mask pattern. Next, only the surface of the sample on the mask pattern side was immersed in a 40% iron (III) chloride aqueous solution (manufactured by Fujifilm Wako Pure Chemical Corporation, first grade), the copper layer on which the mask pattern was not laminated was subjected to an etching treatment, and the mask pattern was peeled off to form a copper wiring line (microstrip line).

A size of the copper wiring line was 10 cm in length and 105 μm in width. In this manner, a first sample in which the copper wiring line was formed on one surface and the copper layer was formed on the entire area of the other surface was obtained.

A sample of a single-sided copper-clad laminate was produced by producing a single-sided copper-clad laminate in the same manner as in the step B of each example, except that the liquid crystal polymer film and one copper foil were laminated, and the produced single-sided copper-clad laminate was cut into pieces in a size of 15 cm×15 cm. The copper layer included in the obtained sample was subjected to the same treatment including the etching treatment as described above to produce a second sample in which a copper wiring line having the same position and size as those of the copper wiring line of the first sample was formed on one surface.

The first sample and the second sample were laminated such that the surface of the first sample on the copper wiring line side and the surface of the second sample, on which the copper wiring line was not formed, were in contact with each other, and the in-plane positions of the copper wiring lines were the same.

The obtained multi-layer laminate was introduced between a pair of heating metal rolls provided in a continuous thermal press machine and subjected to thermocompression. At this time, the surface temperature of the heating metal roll was set to 260° C., and the pressure applied to the multi-layer laminate was set to 40 kg/cm² in terms of a surface pressure.

The multi-layer laminate produced by the above-described method was cut so as to include a lamination direction and to form a cross section perpendicular to a longitudinal direction of each copper wiring line. The obtained cut surface was observed using a scanning electron microscope (SEM). In the observed cross-sectional image, the position of the copper wiring line in the first sample was compared with the position of the copper wiring line in the second sample, and a difference between the position of the copper wiring line in the second sample and the position of the copper wiring line of the first sample in the in-plane direction (lateral direction of the copper wiring line) was measured.

From the measured difference, a misregistration of the metal-clad laminate produced in each of Examples was evaluated based on the following evaluation standard.

(Evaluation Standard for Misregistration)

A: Ratio of the misregistration of the copper wiring line to the thickness of the liquid crystal polymer film was less than 1%.

B: Ratio of the misregistration of the copper wiring line to the thickness of the liquid crystal polymer film was 1% or more and less than 3%.

C: Ratio of the misregistration of the copper wiring line to the thickness of the liquid crystal polymer film was 3% or more and less than 5%.

D: Ratio of the misregistration of the copper wiring line to the thickness of the liquid crystal polymer film was 5% or more.

In addition, in the column of “Peeling surface” of “Evaluation” in Table 3, “LCP Present” indicates that the liquid crystal polymer was attached to a peeling surface of the peeled copper foil, and “Copper foil interface” indicates that the liquid crystal polymer was not attached to a peeling surface of the peeled copper foil.

TABLE 2-1

| | Film | Liquid crystal polymer film | | | | | | | | |
|---|---|---|---|---|---|---|---|---|---|---|
| | form- | | | | Amount of | | | | Dielectric | |
| | ation | | Number- | | heat of | Elastic modulus (Gpa) | | | characteristics | |
| | step | Melting | average | Melt | crystal | Elastic | Elastic | | | Dielectric |
| | Type | point | molecular | viscosity | melting | modulus | modulus | Ratio | Relative | loss |
| | of die | (° C.) | weight | (Pa · s) | (J/g) | B | A | B/A | permittivity | tangent |
| Example 101 | T-die | 330 | 110000 | 330 | 1.8 | 4.7 | 4.8 | 0.98 | 3.3 | 0.0007 |
| Example 102 | T-die | 330 | 110000 | 330 | 1.8 | 4.7 | 4.7 | 1 | 3.3 | 0.0007 |
| Example 103 | T-die | 330 | 110000 | 329 | 1.7 | 4.7 | 4.7 | 1 | 3.3 | 0.0007 |
| Example 104 | T-die | 330 | 110000 | 325 | 1.6 | 4.8 | 4.8 | 1 | 3.3 | 0.0007 |

TABLE 3

| | Evaluation | | | | |
|---|---|---|---|---|---|
| | Tear | Film- | | | |
| | strength | forming | Adhesiveness | Misregis- | Peeling |
| | (g/f) | properties | (N/cm) | tration | surface |
| Example | 55 | B | 7 | B | LCP |
| 101 | | | | | Present |
| Example | 55 | B | 4 | C | LCP |
| 102 | | | | | Present |
| Example | 50 | B | 2.3 | C | LCP |
| 103 | | | | | Present |
| Example | 49 | B | 2.1 | C | LCP |
| 104 | | | | | Present |

From the above results, it was found that the liquid crystal polymer film of the present example has high tear resistance and excellent film-forming properties.

In addition, in Example 101 in which the ratio B/A of the elastic modulus B to the elastic modulus A was 0.99 or less and the elastic modulus A was 4.0 GPa or more, it was found that the performance of suppressing misregistration of the wiring line is excellent.

In Examples 101 and 102, in which the average value of the widths of the void regions was 0.01 to 0.1 μm and the area ratio of the void regions was 20% or less, it was found that the adhesiveness between the metal foil and the liquid crystal polymer film is excellent (the peel strength is excellent).

Furthermore, in Example 101 in which Expression (1A) of (Hardness A+Hardness B)/2≥0.10 GPa and Expression (2A) of Void area proportion Y−Void area proportion X≥0.10% were satisfied, it was found that the dielectric loss tangent is low and the difference in linear expansion coefficiency with the copper foil is small.

The disclosure of Japanese Patent Application No. 2020-166406 filed on Sep. 30, 2020 is incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A liquid crystal polymer film comprising:
a liquid crystal polymer,
wherein the liquid crystal polymer film has a melting point of 315° C. or higher and has a number-average molecular weight of 13,000 or more and 150,000 or less.

2. The liquid crystal polymer film according to claim 1,
wherein the liquid crystal polymer film has a number-average molecular weight of 18,000 or more and 150,000 or less.

3. The liquid crystal polymer film according to claim 1,
having a melt viscosity of 80 Pa·s or more and 400 Pa·s or less in a case where a temperature is set to be higher than the melting point by 5° C. and a shear rate is set to be 1000 sec⁻¹.

4. The liquid crystal polymer film according to claim 1,
having an amount of heat of crystal melting, which is determined by a differential scanning calorimetry, of 2 J/g or less.

5. The liquid crystal polymer film according to claim 1,
wherein the liquid crystal polymer film is used in a flexible printed circuit board.

6. A flexible copper-clad laminated board comprising:
the liquid crystal polymer film according to claim 1; and
a copper foil disposed on at least one surface of the liquid crystal polymer film.

7. A manufacturing method of the liquid crystal polymer film according to claim 1, the manufacturing method comprising:
extruding a melt-kneaded liquid crystal polymer with a T-die to form a film.

8. The liquid crystal polymer film according to claim 1,
wherein, in a cross section of the liquid crystal polymer film along a thickness direction of the liquid crystal polymer film, in a case where an elastic modulus at a position A at a distance of half of a thickness of the liquid crystal polymer film from one surface toward the other surface of the liquid crystal polymer film is defined as an elastic modulus A and an elastic modulus at a position B at a distance of ⅛ of the thickness of the liquid crystal polymer film from one surface toward the other surface of the liquid crystal polymer film is defined as an elastic modulus B, a ratio B/A of the elastic modulus B to the elastic modulus A is 0.99 or less and the elastic modulus A is 4.0 GPa or more.

9. The liquid crystal polymer film according to claim 8,
wherein the elastic modulus A is 4.6 GPa or more.

10. The liquid crystal polymer film according to claim 1,
wherein in a case where a cross section of the liquid crystal polymer film along a thickness direction of the liquid crystal polymer film is exposed and immersed in monomethylamine, and then void regions are extracted from an observed image of the cross section, obtained by using an electron microscope, an average value of widths of the void regions is 0.01 to 0.1 μm, and
an area ratio of the void regions in the observed image of the cross section is 20% or less.

11. The liquid crystal polymer film according to claim 10,
wherein the void regions have an average length of 3 to 5 μm.

12. The liquid crystal polymer film according to claim 10,
wherein the liquid crystal polymer film has a thickness of 15 μm or more and satisfies Requirement A,
Requirement A: in the cross section, in a case where a region where a distance from one surface of the liquid crystal polymer film is within 5 μm is defined as a first surface layer region, a region where a distance from the other surface of the liquid crystal polymer film is within 5 μm is defined as a second surface layer region, and a region within 2.5 μm from a center line equidistant from both surfaces of the liquid crystal polymer film is defined as a central layer region, an area ratio of void regions in the central layer region is higher than an area ratio of void regions in the first surface layer region and is also higher than an area ratio of void regions in the second surface layer region.

13. The liquid crystal polymer film according to claim 1,
wherein, in a cross section of the liquid crystal polymer film along a thickness direction of the liquid crystal polymer film, in a case where a hardness at a position A at a distance of half of a thickness of the liquid crystal polymer film from one surface toward the other surface of the liquid crystal polymer film is defined as a hardness A and a hardness at a position B at a distance of 1/10 of the thickness of the liquid crystal polymer film from one surface toward the other surface of the liquid crystal polymer film is defined as a hardness B, the hardness A and the hardness B satisfy a relationship of Expression (1A), and
in the cross section, in a case where a position at the distance of 1/10 of the thickness of the liquid crystal polymer film from the one surface toward the other surface of the liquid crystal polymer film is defined as a position T1, a position at a distance of 4/10 of the thickness of the liquid crystal polymer film from the one surface toward the other surface of the liquid crystal polymer film is defined as a position T2, and a position at a distance of 6/10 of the thickness of the liquid crystal polymer film from the one surface toward the other surface of the liquid crystal polymer film is defined as a position T3, a region from the one surface to the position T1 is defined as an S region, and a region from the position T2 to the position T3 is defined as a C region, an area ratio of void regions in the S region is defined as a void area proportion X, and an area ratio of void regions in the C region is defined as a void area proportion Y, the void area proportion X and the void area proportion Y satisfy a relationship of Expression (2A),
(Hardness A+Hardness B)/2≥0.10 GPa Expression (1A)
Void area proportion Y−Void area proportion X≥0.10%. Expression (2A)

14. The liquid crystal polymer film according to claim 13,
wherein the hardness A and the hardness B satisfy a relationship of Expression (1B),
(Hardness A−Hardness B)≥−0.02 GPa. Expression (1B)

15. The liquid crystal polymer film according to claim 1,
wherein the liquid crystal polymer film has a monolayer structure.

16. The liquid crystal polymer film according to claim 1,
wherein the liquid crystal polymer film has a dielectric loss tangent of 0.0022 or less at a temperature of 23° C. and a frequency of 28 GHz.

17. The liquid crystal polymer film according to claim 1,
wherein the liquid crystal polymer has at least one selected from the group consisting of a repeating unit derived from parahydroxybenzoic acid and a repeating unit derived from 6-hydroxy-2-naphthoic acid.

18. The liquid crystal polymer film according to claim 1,
wherein the liquid crystal polymer has at least one selected from the group consisting of a repeating unit derived from 6-hydroxy-2-naphthoic acid, a repeating unit derived from an aromatic diol compound, a repeating unit derived from terephthalic acid, and a repeating unit derived from 2,6-naphthalenedicarboxylic acid.

19. The liquid crystal polymer film according to claim 1, further comprising:
a polyolefin,
wherein a content of the polyolefin is 40% by mass or less with respect to a total mass of the liquid crystal polymer film.
